(19) United States
(12) Patent Application Publication
(10) Pub. No.: US 2024/0284678 A1
(43) Pub. Date: Aug. 22, 2024

(54) SEMICONDUCTOR DEVICE AND ELECTRONIC SYSTEM INCLUDING THE SAME

(71) Applicant: Samsung Electronics Co., Ltd., Suwon-si (KR)

(72) Inventor: Kijoon KIM, Suwon-si (KR)

(73) Assignee: Samsung Electronics Co., Ltd., Suwon-si (KR)

(21) Appl. No.: 18/488,409

(22) Filed: Oct. 17, 2023

(30) Foreign Application Priority Data
Feb. 22, 2023 (KR) 10-2023-0023650

(51) Int. Cl. H10B 51/20

(52) U.S. Cl. CPC H10B 51/20

(57) ABSTRACT

A semiconductor device including a stack structure including a plurality of gate lines and a plurality of insulating patterns, the plurality of gate lines being apart from each other in a vertical direction, the plurality of insulating patterns being one-by-one between the plurality of gate lines, the stack structure including a vertical hole passing therethrough in the vertical direction, a channel film extending in the vertical direction inside the vertical hole, and a composite domain dielectric film between the channel film and the stack structure, wherein the composite domain dielectric film includes a main domain including a ferroelectric material, the main domain extending in the vertical direction inside the vertical hole, and at least one sub-domain including at least one material selected from an anti-ferroelectric material and a paraelectric material, the at least one sub-domain being in contact with the main domain may be provided.

### CROSS-REFERENCE TO RELATED APPLICATION

This application is based on and claims priority under 35 U.S.C. § 119 to Korean Patent Application No. 10-2023-0023650, filed on Feb. 22, 2023, in the Korean Intellectual Property Office, the disclosure of which is incorporated by reference herein in its entirety.

### BACKGROUND

The inventive concepts relates to semiconductor device and/or electronic systems including the same, and more particularly, to semiconductor devices including a vertical memory device and/or electronic systems including the semiconductor device.

As semiconductor devices are gradually becoming lager in capacity and higher in integration density, a vertical memory device in which a plurality of memory cells are stacked on a substrate in a vertical direction to increase memory capacity has been proposed. When the stacking density of cells in a vertical direction is increased in the vertical memory device, a distance between adjacent cells in the vertical direction may be reduced. Thus, reliability of the semiconductor devices may deteriorate due to cell interface between the adjacent cells.

### SUMMARY

Some example embodiments of the inventive concepts provide semiconductor devices, which includes memory cells three-dimensionally arranged in an area, which is reduced with the downscaling trend, and may structurally improve electrical characteristics and reliability.

Some example embodiments of the inventive concepts also provide electronic systems including a semiconductor device, which includes memory cells three-dimensionally arranged in an area, which is reduced with the downscaling trend, and may structurally improve electrical characteristics and reliability.

According to an example embodiment of the inventive concepts, a semiconductor device may include a stack structure including a plurality of gate lines and a plurality of insulating patterns, the plurality of gate lines being apart from each other in a vertical direction, the plurality of insulating patterns being one-by-one between the plurality of gate lines, the stack structure including a vertical hole passing therethrough in the vertical direction, a channel film extending in the vertical direction inside the vertical hole, and a composite domain dielectric film between the channel film and the stack structure, wherein the composite domain dielectric film includes a main domain including a ferroelectric material, the main domain extending long in the vertical direction inside the vertical hole, and at least one sub-domain including at least one material selected from an anti-ferroelectric material and a paraelectric material, the at least one sub-domain being in contact with the main domain.

According to an example embodiment of the inventive concepts, a semiconductor device may include a conductive layer, a stack structure including a plurality of gate lines and a plurality of insulating patterns, the plurality of gate lines overlapping each other in a vertical direction on the conductive layer, the plurality of gate lines being apart from each other in the vertical direction, the plurality of insulating patterns being one-by-one between the plurality of gate lines, the stack structure including a vertical hole passing therethrough in the vertical direction, a conductive pad apart from the conductive layer with the stack structure therebetween in the vertical direction, a channel film extending in the vertical direction inside the vertical hole, the channel film having a first channel end portion in contact with the conductive pad and a second channel end portion adjacent to the conductive layer, an insulating plug surrounded by the channel film, and a composite domain dielectric film between the channel film and the stack structure, the composite domain dielectric film having a first end portion in contact with the conductive pad and a second end portion in contact with the conductive layer, wherein the composite domain dielectric film includes a main domain including a ferroelectric material, the main domain extending long in the vertical direction inside the vertical hole, at least one sub-domain including at least one material selected from an anti-ferroelectric material and a paraelectric material, the at least one sub-domain being in contact with the main domain.

According to an example embodiment of the inventive concepts, an electronic system may include a main substrate, a semiconductor device on the main substrate, and a controller electrically connected to the semiconductor device on the main substrate, wherein the semiconductor device includes a stack structure including a plurality of gate lines and a plurality of insulating patterns, the plurality of gate lines being apart from each other in a vertical direction, and the plurality of insulating patterns being one-by-one between the plurality of gate lines, the stack structure including a vertical hole passing therethrough in the vertical direction, a channel film extending in the vertical direction inside a vertical hole, and a composite domain dielectric film between the channel film and the stack structure, and wherein the composite domain dielectric film includes a main domain including a ferroelectric material, the main domain extending long in the vertical direction inside the vertical hole, and at least one sub-domain including at least one material selected from an anti-ferroelectric material and a paraelectric material, the at least one sub-domain being in contact with the main domain.

### BRIEF DESCRIPTION OF THE DRAWINGS

Example embodiments of the inventive concepts will be more clearly understood from the following detailed description taken in conjunction with the accompanying drawings in which:

FIG. 1 is a block diagram of a semiconductor device according to an example embodiment;

FIG. 2A illustrates a plan layout of some components of a cell array structure of a semiconductor device according to an example embodiment;

FIG. 2B is a cross-sectional view of partial regions corresponding to a cross-section taken along line X1-X1′ of FIG. 2A;

FIG. 2C is an enlarged cross-sectional view of region “EX1A” of FIG. 2B;

FIG. 2D is an enlarged cross-sectional view of region “EX1B” of FIG. 2B;

FIG. 3 is a cross-sectional view of a semiconductor device according to an example embodiment;

FIGS. 4 to 9 are cross-sectional view of a semiconductor device according to an example embodiment;

FIGS. 10A to 10C are cross-sectional views of partial regions of a semiconductor device memory cell array according to an example embodiment, wherein FIG. 10B is an enlarged cross-sectional view of region “EX2A” of FIG. 10A, and FIG. 10C is an enlarged cross-sectional view of region “EX2B” of FIG. 10A;

FIGS. 11 to 17 are each a cross-sectional view of a semiconductor device according to an example embodiment;

FIGS. 18 to 26 are cross-sectional views of a method of manufacturing a semiconductor device, according to an example embodiment, wherein FIGS. 18, 19A, 20, 21A, 22A, and 23 to 26 are each an enlarged cross-sectional view of a region corresponding to region “EX1A” of FIG. 2B, according to a process sequence, and FIGS. 19B, 21B, and 22B are respectively enlarged cross-sectional views of regions “EX1B” of FIGS. 19A, 21A, and 22A;

FIGS. 27A to 27F are cross-sectional views of a method of manufacturing a semiconductor device, according to an example embodiment;

FIGS. 28A to 28C are cross-sectional views of a method of manufacturing a semiconductor device, according to an example embodiment;

FIGS. 29A to 29H are cross-sectional views of a method of manufacturing a semiconductor device, according to an example embodiment;

FIGS. 30A to 30E are cross-sectional views of a method of manufacturing a semiconductor device, according to an example embodiment;

FIG. 31 is a diagram of an electronic system including a semiconductor device, according to an example embodiment;

FIG. 32 is a perspective view of an electronic system including a semiconductor device, according to an example embodiment; and

FIG. 33 is a cross-sectional view of a semiconductor package according to an example embodiment.

### DETAILED DESCRIPTION

Hereinafter, some example embodiments will be described in detail with reference to the accompanying drawings. The same reference numerals are used to denote the same elements in the drawings, and repeated descriptions thereof are omitted.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

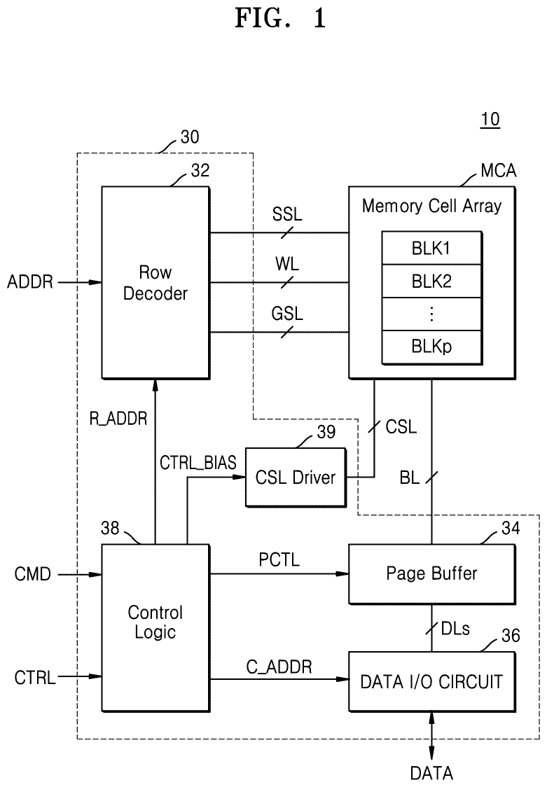

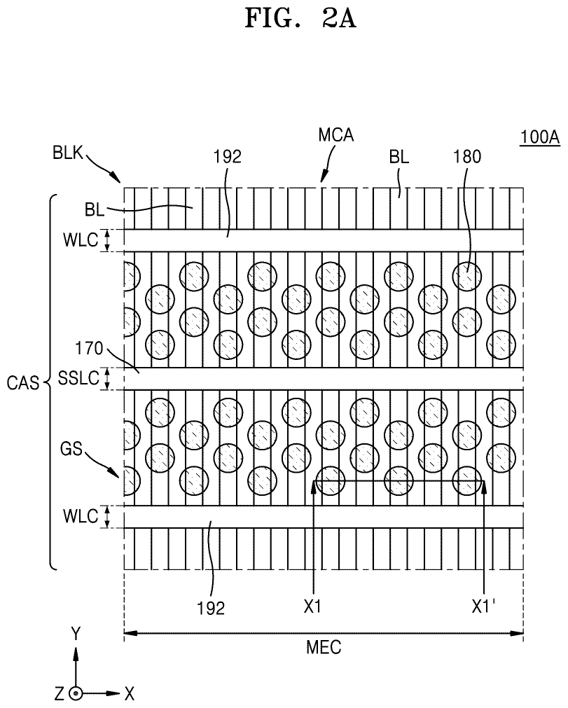

FIG. 1 is a block diagram of a semiconductor device 10 according to an example embodiment.

Referring to FIG. 1, the semiconductor device 10 may include a memory cell array MCA and a peripheral circuit 30. The memory cell array MCA may include a plurality of memory cell blocks BLK1, BLK2, . . . , and BLKp. Each of the plurality of memory cell blocks BLK1, BLK2, . . . , and BLKp may include a plurality of memory cells. The memory cell blocks BLK1, BLK2, . . . , and BLKp may be connected to the peripheral circuit 30 through a bit line BL, a word line WL, a string selection line SSL, and a ground selection line GSL.

The peripheral circuit 30 may include a row decoder 32, a page buffer 34, a data input/output (I/O) circuit 36, a control logic 38, and a common source line driver 39. The peripheral circuit 30 may further include various circuits, such as a voltage generating circuit configured to generate various voltages desired for operations of the semiconductor device 10, an error correction circuit configured to correct errors in data read from the memory cell array MCA, an I/O interface, and the like.

The memory cell array MCA may be connected to the row decoder 32 through the word line WL, the string selection line SSL, and the ground selection line GSL and be connected to the page buffer 34 through the bit line BL. In the memory cell array MCA, each of the plurality of memory cells in each of the plurality of memory cell blocks BLK1, BLK2, . . . , and BLKp may include a flash memory cell. The memory cell array MCA may include a three-dimensional (3D) memory cell array. The 3D memory cell array may include a plurality of NAND strings, and each of the plurality of NAND strings may include a plurality of memory cells respectively connected to a plurality of word lines WL that are stacked vertically.

The peripheral circuit 30 may receive an address ADDR, a command CMD, and a control signal CTRL from the outside of the semiconductor device 10 and transmit and receive data DATA to and from a device located outside the semiconductor device 10.

The row decoder 32 may select at least one of the plurality of memory cell blocks BLK1, BLK2, . . . , and BLKp in response to the address ADDR transmitted from the outside, and select the word line WL, the string selection line SSL, and the ground selection line GSL of the selected memory cell block. The row decoder 32 may transmit a voltage for performing a memory operation to the word line WL of the selected memory cell block.

The page buffer 34 may be connected to the memory cell array MCA through the bit line BL. In a program operation, the page buffer 34 may operate as a write driver and apply a voltage corresponding to the data DATA to be stored in the memory cell array MCA, to the bit line BL. In a read operation, the page buffer 34 may operate as a sense amplifier and sense the data DATA stored in the memory cell array MCA. The page buffer 34 may operate in response to a control signal PCTL provided from the control logic 38.

The data I/O circuit 36 may be connected to the page buffer 34 through a plurality of data lines DLs. In the program operation, the data I/O circuit 36 may receive the data DATA from a memory controller (not shown) and provide program data DATA to the page buffer 34 based on a column address C_ADDR provided from the control logic 38. In the read operation, the data I/O circuit 36 may provide the read data DATA stored in the page buffer 34 to the memory controller, based on the column address C_ADDR provided from the control logic 38.

The data I/O circuit 36 may transmit an input address or instruction to the control logic 38 or the row decoder 32. The peripheral circuit 30 may further include an electrostatic discharge (ESD) circuit and a pull-up/pull-down driver.

The control logic 38 may receive the command CMD and the control signal CTRL from the memory controller. The control logic 38 may provide a row address R_ADDR to the row decoder 32 and provide the column address C_ADDR to the data I/O circuit 36. The control logic 38 may generate various internal control signals used in the semiconductor device 10, in response to the control signal CTRL. For example, the control logic 38 may control a voltage level provided to the word line WL or the bit line BL during a memory operation, such as the program operation or an erase operation.

The common source line driver 39 may be connected to the memory cell array MCA through a common source line CSL. The common source line driver 39 may apply a common source voltage (e.g., a power supply voltage) or a ground voltage to the common source line CSL, based on a control signal CTRL_BIAS of the control logic 38.

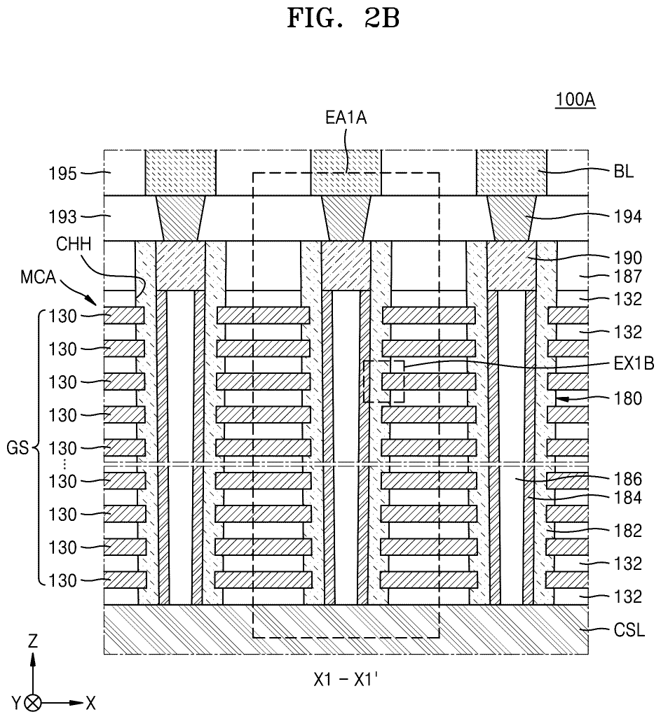

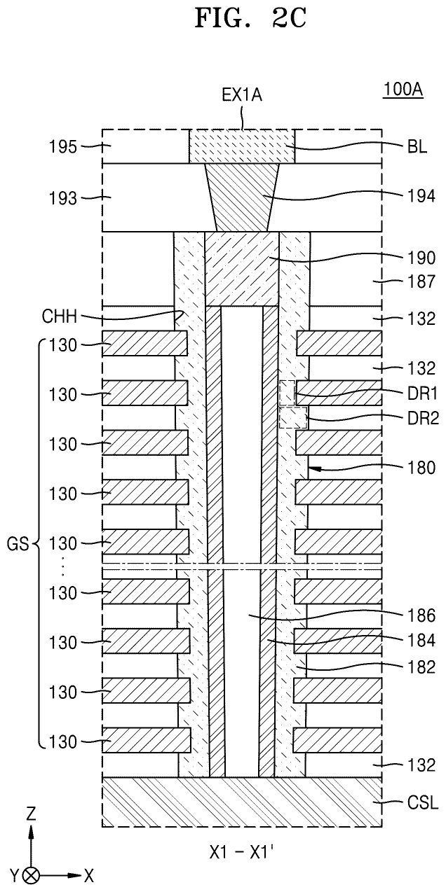

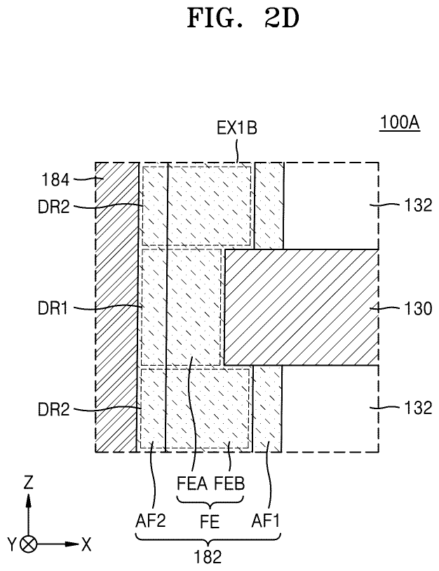

FIG. 2A illustrates a plan layout of some components of a cell array structure CAS of a semiconductor device 100A according to an example embodiment. FIG. 2B is a cross-sectional view of partial regions corresponding to a cross-section taken along line X1-X1′ of FIG. 2A in the cell array structure CAS of the semiconductor device 100A. FIG. 2C is an enlarged cross-sectional view of region “EX1A” of FIG. 2B. FIG. 2D is an enlarged cross-sectional view of region “EX1B” of FIG. 2B. FIGS. 2A and 2B illustrate some components of the memory cell block BLK corresponding to a selected one of the plurality of memory cell blocks BLK1, BLK2, . . . , and BLKp shown in FIG. 1.

Referring to FIGS. 2A to 2D, the semiconductor device 100A may include the cell array structure CAS, and the cell array structure CAS may include a memory cell region MEC in which a memory cell array MCA is located.

The cell array structure CAS may include a common source line CSL and the memory cell array MCA on the common source line CSL. The memory cell array MCA may include a gate stack GS including a plurality of gate lines 130. The plurality of gate lines 130 in the gate stack GS may extend parallel to the common source line CSL in a lateral direction and overlap each other in a vertical direction (Z direction). The plurality of gate lines 130 may include the plurality of word lines WL, the ground selection line GSL, and string selection line SSL, which are shown in FIG. 1.

As shown in FIG. 2B, the cell array structure CAS may include a stack structure, which includes the gate stack GS and a plurality of insulating patterns 132. The gate stack GS may include the plurality of gate lines 130, which overlap each other in the vertical direction (Z direction) on the common source line CSL and are apart from each other in the vertical direction (Z direction). The plurality of insulating patterns 132 may be one-by-one between the common source line CSL and the plurality of gate lines 130 and between the plurality of gate lines 130. The stack structure may further include a middle insulating film 187, which covers an uppermost one of the plurality of insulating patterns 132. From among the plurality of gate lines 130, a gate line 130 that is most adjacent to a conductive pad 190, may be covered by the insulating pattern 132 and the middle insulating film 187. Each of the plurality of insulating patterns 132 and the middle insulating film 187 may include silicon oxide, silicon nitride, or SiON.

A plurality of conductive pads 190 may be apart from the common source line CSL in the vertical direction (X direction) with the stack structure including the plurality of gate lines 130 and the plurality of insulating patterns 132 therebetween. As used herein, the common source line CSL may be referred to as a conductive layer.

Each of the plurality of gate lines 130 may include a metal, a conductive metal nitride, a metal silicide, a doped semiconductor, or a combination thereof. For example, each of the plurality of gate lines 130 may include tungsten, nickel, cobalt, tantalum, tungsten nitride, titanium nitride, tantalum nitride, doped polysilicon, tungsten silicide, nickel silicide, cobalt silicide, tantalum silicide, or a combination thereof, without being limited thereto.

Each of the plurality of conductive pads 190 and the common source line CSL may include a semiconductor material, a metal, a conductive metal nitride, or a combination thereof. For instance, each of the plurality of conductive pads 190 and the common source line CSL may include doped polysilicon, tungsten, titanium, tantalum, copper, aluminum, titanium nitride, tantalum nitride, tungsten nitride, or a combination thereof, without being limited thereto.

The cell array structure CAS may include a plurality of vertical holes CHH and a plurality of channel structures 180. The plurality of vertical holes CHH may pass through the stack structure in the vertical direction (Z direction). The plurality of channel structures 180 may pass through the plurality of gate lines 130 and the plurality of insulating patterns 132, which are included in the stack structure, in the vertical direction (Z direction) inside the plurality of vertical holes CHH. Each of the plurality of channel structures 180 may include a composite domain dielectric film 182, a channel film 184, and an insulating plug 186, which are sequentially stacked from the plurality of gate lines 130 toward the channel structure 180.

The channel film 184 may extend long in the vertical direction (Z direction) inside the vertical hole CHH. One end portion of the channel film 184 may be in contact with the conductive pad 190, and another end portion of the channel film 184 may be in contact with the common source line CSL. As used herein, the one end portion of the channel film 184, which is in contact with the conductive pad 190, may be referred to as a first channel end portion, and the other end portion of the channel film 184, which is in contact with the common source line CSL, may be referred to as a second channel end portion. The insulating plug 186 may be surrounded by the channel film 184.

The composite domain dielectric film 182 may extend long in the vertical direction (Z direction) inside the vertical hole CHH to be between the channel film 184 and the plurality of gate lines 130 included in the stack structure and between the channel film 184 and the plurality of insulating patterns 132 included in the stack structure. One end portion of the composite domain dielectric film 182 may be in contact with the conductive pad 190, and another end portion of the composite domain dielectric film 182 may be in contact with the common source line CSL. As used herein, the one end portion of the composite domain dielectric film 182, which is in contact with the conductive pad 190, may be referred to as a first end portion, and the other end portion of the composite domain dielectric film 182, which is in contact with the common source line CSL, may be referred to as a second end portion. In a lateral direction (e.g., X direction in FIGS. 2B to 2D), a width of the composite domain dielectric film 182 may vary in the vertical direction (Z direction).

As shown in FIG. 2D, the composite domain dielectric film 182 may include a main domain FE and at least one sub-domain in contact with the main domain FE. The main domain FE may extend long in the vertical direction (Z direction) inside the vertical hole CHH. The main domain FE may face each of the plurality of gate lines 130 and the plurality of insulating patterns 132 in the lateral direction (e.g., X direction in FIGS. 2B to 2D).

A width of the main domain FE in the lateral direction may be variable along the vertical direction (Z direction). The main domain FE may include a plurality of first main domain portions FEA and a plurality of second main domain portions FEB. The plurality of first main domain portions FEA may be between the channel film 184 and the plurality of gate lines 130. The plurality of second main domain portions FEB may between the channel film 184 and the plurality of insulating patterns 132. The plurality of first main domain portions FEA may be integrally connected to the plurality of second main domain portions FEB. In the lateral direction, a width of each of the plurality of first main domain portions FEA may be less than a width of each of the plurality of second main domain portions FEB. The main domain FE may include a ferroelectric material.

The at least one sub-domain included in the composite domain dielectric film 182 may include a plurality of first sub-domains AF1 and a second sub-domain AF2, which are apart from each other with the main domain FE therebetween in the lateral direction. The plurality of first sub-domains AF1 may be between the plurality of insulating patterns 132 and the main domain FE. The plurality of first sub-domains AF1 may be arranged in a straight line parallel to the main domain FE and be apart from each other in the vertical direction (Z direction). The second sub-domain AF2 may be between the main domain FE and the channel film 184. The second sub-domain AF2 may extend long along the channel film 184 in the vertical direction (Z direction).

Each of the plurality of first sub-domains AF1 may include a portion in contact with a selected one of the plurality of insulating patterns 132 and a portion in contact with the main domain FE. The second sub-domain AF2 may include a portion in contact with the main domain FE and a portion in contact with the channel film 184. Each of the plurality of first sub-domains AF1 and the second sub-domain AF2 may include at least one material selected from an anti-ferroelectric material and a paraelectric material.

As shown in FIG. 2D, the composite domain dielectric film 182 may include a plurality of first dielectric regions DR1 and a plurality of second dielectric regions DR2. The plurality of first dielectric regions DR1 may face the plurality of gate lines 130 in the lateral direction (e.g., X direction in FIGS. 2B to 2D) and be apart from each other in the vertical direction (Z direction). The plurality of second dielectric regions DR2 may face the plurality of insulating patterns 132 in the lateral direction and be apart from each other in the vertical direction (Z direction). The plurality of first dielectric regions DR1 may have different stack structures from the plurality of second dielectric regions DR2. In the lateral direction, the plurality of first dielectric regions DR1 may have different widths from the plurality of second dielectric regions DR2. FIGS. 2B to 2D illustrates a configuration in which a width of each of the plurality of first dielectric regions DR1 is less than a width of each of the plurality of second dielectric regions DR2 in the lateral direction. However, the inventive concepts are not limited thereto, and a width of each of the plurality of first dielectric regions DR1 and the plurality of second dielectric regions DR2 may be variously selected within the scope of the inventive concepts.

In the composite domain dielectric film 182, a width of each of the main domain FE, the plurality of first sub-domains AF1, and the second sub-domain AF2 may be selected in a range of about 0.5 Å to about 100 Å, for example, a range of about 1 Å to about 50 Å in the lateral direction (e.g., X direction in FIGS. 2B to 2D). In some example embodiments, as shown in FIG. 2D, in the composite domain dielectric film 182, a width of the main domain FE may be greater than a width of each of the plurality of first sub-domains AF1 and the second sub-domain AF2 in the lateral direction. In some example embodiments, in the lateral direction, a width of the main domain FE may be about 2 times to 10 times (e.g., about 3 times to about 5 times) a width of each of the plurality of first sub-domains AF1 and the second sub-domain AF2. For instance, a width of each of the plurality of first sub-domains AF1 and the second sub-domain AF2 may be selected in a range of about 4 Å to about 30 Å, and a width of the main domain FE may be selected in a range of about 10 Å to about 100 Å, without being limited thereto.

FIG. 2D illustrates a configuration in which a width of the main domain FE is greater than a width of each of the plurality of first sub-domains AF1 and the second sub-domain AF2 in the lateral direction, but the inventive concepts are not limited thereto. In the composite domain dielectric film 182, a width of each of the main domain FE, the plurality of first sub-domains AF1, and the second sub-domain AF2 in a lateral direction may vary as desired.

In the composite domain dielectric film 182, the main domain FE may include a ferroelectric material, and each of the plurality of first sub-domains AF1 and the second sub-domain AF2 may include at least one material selected from an anti-ferroelectric material and a paraelectric material. In an example, the main domain FE may include a ferroelectric material, and each of the plurality of first sub-domains AF1 and the second sub-domain AF2 may include an anti-ferroelectric material. In another example, the main domain FE may include a ferroelectric material, and each of the plurality of first sub-domains AF1 and the second sub-domain AF2 may include a paraelectric material. In still another example, the main domain FE may include a ferroelectric material, the plurality of first sub-domains AF1 may include an anti-ferroelectric material, and the second sub-domain AF2 may include a paraelectric material. In yet another example, the main domain FE may include a ferroelectric material, the plurality of first sub-domains AF1 may include a paraelectric material, and the second sub-domain AF2 may include an anti-ferroelectric material.

The ferroelectric material that may be used to form the main domain FE of the composite domain dielectric film 182 may include at least one oxide selected from hafnium (Hf), silicon (Si), aluminum (Al), zirconium (Zr), yttrium (Y), lanthanum (La), gadolinium (Gd), and strontium (Sr). For example, the ferroelectric material may include hafnium oxide (HfO), hafnium zirconium oxide (HZO), hafnium titanium oxide, or hafnium silicon oxide. The ferroelectric material may further include a dopant as desired. The dopant may include at least one element selected from silicon (Si), aluminum (Al), zirconium (Zr), yttrium (Y), lanthanum (La), gadolinium (Gd), scandium (Sc), strontium (Sr), magnesium (Mg), or barium (Ba), without being limited thereto.

In the composite domain dielectric film 182, the anti-ferroelectric material that may be used to form the plurality of first sub-domains AF1 and/or the second sub-domain AF2 may include hafnium oxide (HfO) or zirconium oxide (ZrO). As used herein, each of the terms “HfO” and “ZrO” refers to a material containing elements included therein, without referring to a chemical formula representing a stoichiometric relationship.

In some example embodiments, the anti-ferroelectric material may include the same constituent materials as the ferroelectric material that may be used to form the main domain FE, but the anti-ferroelectric material may have different crystalline phases from the ferroelectric materials of the main domain FE. For example, the ferroelectric material may include a Hf-based oxide or Zr-based oxide having an orthorhombic crystalline phase, and the anti-ferroelectric material may include a Hf-based oxide or Zr-based oxide having a monoclinic crystalline phase. The Hf-based oxide may include HfO₂, and the Zr-based oxide may include ZrO₂.

In the composite domain dielectric film 182, the paraelectric material that may be used to form the plurality of first sub-domains AF1 and/or the second sub-domain AF2 may include silicon oxide, silicon nitride, silicon oxynitride, or a combination thereof.

In some example embodiments, in the composite domain dielectric film 182, the main domain FE may include a ferroelectric HfO₂ film, and each of the plurality of first sub-domains AF1 and the second sub-domain AF2 may include an anti-ferroelectric ZrO₂ film. The composite domain dielectric film 182 may have a multilayered structure in which a ferroelectric material film and an anti-ferroelectric material film are alternately stacked to form a superlattice structure.

The composite domain dielectric film 182 may have improved spontaneous polarization characteristics and an increased relative dielectric constant. Even when the composite domain dielectric film 182 is thinned to a thickness of 100 Å or less, for example, 50 Å or less, the composite domain dielectric film 182 may maintain ferroelectric characteristics and have improved data retention characteristics. In addition, in the composite domain dielectric film 182, the plurality of first dielectric regions DR1 facing the plurality of gate lines 130 may have different stack structures and different widths from the plurality of second dielectric regions DR2 facing the plurality of insulating patterns 132. Thus, undesired coupling effects, which may occur between the plurality of gate lines 130, may be reduced. Accordingly, reliability of the semiconductor device 100A may improve.

In example embodiments, the channel film 184 may include polysilicon, an oxide semiconductor, a two-dimensional (2D) semiconductor material, or a combination thereof. The polysilicon may include doped polysilicon, without being limited thereto.

The oxide semiconductor that may be used to form the channel film 184 may be selected from indium gallium zinc oxide (InGaZnO or IGZO), tin-doped IGZO (Sn-IGZO), indium tungsten oxide (InWO or IWO), InZnO (IZO), zinc tin oxide (ZnSnO or ZTO), zinc oxide (ZnO), yttrium-doped zinc oxide (YZO), indium gallium silicon oxide (InGaSiO or IGSO), indium (InO), tin oxide (SnO), titanium oxide (TiO), zinc oxynitride (ZnON), magnesium zinc oxide (MgZnO), zirconium indium zinc oxide (ZrInZnO), hafnium indium zinc oxide (HfInZnO), tin indium zinc oxide (SnInZnO), silicon indium zinc oxide (SiInZnO), gallium zinc tin oxide (GaZnSnO), zirconium zinc tin oxide (ZrZnSnO), or a combination thereof. In some example embodiments, at least a portion of the channel film 184 may include the same elements as those of the oxide semiconductor and further include at least one dopant selected from aluminum (Al), boron (B), arsenic (As), fluorine (F), and hydrogen (H).

In some example embodiments, the 2D semiconductor material that may be used to form the channel film 184 may be selected from graphene, black phosphorous, a transition metal chalcogenide, and a combination thereof. The transition metal chalcogenide may include a combination of a transition metal selected from nickel (Ni), copper (Cu), zinc (Zn), molybdenum (Mo), tungsten (W), niobium (Nb), vanadium (V), tantalum (Ta), titanium (Ti), zirconium (Zr), hafnium (Hf), technetium (Tc), and rhenium (Re) and a chalcogen element selected from S, Se, and Te. For example, the channel film 184 may include MoS₂, MoSe₂, MoTe₂, WS₂, WSe₂, WTe₂, ZrS₂, ZrSe₂, HfS₂, HfSe₂, NbSe₂, ReSe₂, CuS, or a combination thereof, without being limited thereto.

In other example embodiments, the 2D semiconductor material that may be used to form the channel film 184 may include a chalcogenide material including a non-transition metal. The non-transition metal may be selected from gallium (Ga), indium (In), tin (Sn), germanium (Ge), and lead (Pb). For example, the channel film 184 may include SnSe₂, GaS, GaSe, GaTe, GeSe, In₂Se₃, InSnS₂, or a combination thereof, without being limited thereto.

In still other example embodiments, the channel film 184 may include a p-type oxide semiconductor, an n-type an oxide semiconductor, or a combination thereof. The p-type an oxide semiconductor may be selected from nickel oxide (NiO), copper oxide, tin oxide (SnO), copper aluminum oxide (CuAlO₂), copper chromium oxide (CuCrO₂), beta tellurium dioxide (β-TeO₂), and a combination thereof. The copper oxide may include CuO or Cu₂O, without being limited thereto. The n-type an oxide semiconductor may be selected from indium oxide (In₂O₃), tin oxide (SnO₂), zinc oxide (ZnO), IGZO, and a combination thereof. The tin oxide may exhibit p-type characteristics when the tin oxide is in the form of SnO, and exhibit n-type characteristics when the tin oxide is in the form of SnO₂.

In some example embodiments, to adjust carrier mobility of the channel film 184, the channel film 184 may further include a p-type dopant or an n-type dopant. The channel film 184 may have a thickness of about 10 nm to about 20 nm (e.g., about 12 nm to about 18 nm) in a lateral direction (e.g., X direction), without being limited thereto.

The channel film 184 may have a cylindrical shape to define a columnar space extending long in the vertical direction (Z direction) therein. The channel film 184 may be in contact with a selected or corresponding one of the plurality of conductive pads 190.

The insulating plug 186 may be in the columnar space defined by the channel film 184. The insulating plug 186 may fill a space between the conductive pad 190 and the common source line CSL in the columnar space defined by the channel film 184. The insulating plug 186 may have a surface in contact with the channel film 184. The insulating plug 186 may include a silicon oxide film, without being limited thereto.

In the cell array structure CAS, a plurality of bit lines BL may be on the plurality of channel structures 180. A plurality of bit line contact pads 194 may be between the plurality of channel structures 180 and the plurality of bit lines BL. The conductive pad 190 located on one end portion of each of the plurality of channel structures 180 may be connected to a corresponding one of the plurality of bit lines BL through the bit line contact pad 194. The plurality of bit line contact pads 194 may be insulated from each other by a first upper insulating film 193.

A portion of the composite domain dielectric film 182 may be between the conductive pad 190 and the first upper insulating film 193. The plurality of bit lines BL may be insulated from each other by a second upper insulating film 195. Each of the plurality of bit line contact pads 194 and the plurality of bit lines BL may include a metal, a conductive metal nitride, or a combination thereof. For example, each of the plurality of bit line contact pads 194 and the plurality of bit lines BL may include tungsten, titanium, tantalum, copper, aluminum, titanium nitride, tantalum nitride, tungsten nitride, or a combination thereof. Each of the first upper insulating film 193 and the second upper insulating film 195 may include a silicon oxide film, a silicon nitride film, or a combination thereof.

As shown in FIG. 2A, in a cell array structure CAS, a plurality of word line cut regions WLC may extend in a first lateral direction (X direction). The plurality of word line cut regions WLC may define a width of the gate stack GS in a second lateral direction (Y direction). Each of the plurality of word line cut regions WLC may be filled by a word line cut structure 192. The word line cut structure 192 may include an insulating film, a polysilicon film, a metal film, or a combination thereof. In some example embodiments, the word line cut structure 192 may include a silicon oxide film, a silicon nitride film, a polysilicon film, a tungsten film, or a combination thereof, without being limited thereto.

In the memory cell array MCA, two string selection lines (refer to SSL in FIG. 1), which are adjacent to each other in the second lateral direction (Y direction), may be apart from each other with a string selection line cut region SSLC therebetween. The string selection line cut region SSLC may be filled by an insulating film 170. The insulating film 170 may include an oxide film, a nitride film, or a combination thereof. In some example embodiments, at least a portion of the string selection line cut region SSLC may be filled by an air gap. As used herein, the term “air” may refer to the atmosphere or other gases that may be during a manufacturing process.

In the semiconductor device 100A described with reference to FIGS. 2A to 2D, the composite domain dielectric film 182 may have a multilayered structure in which a ferroelectric material film and an anti-ferroelectric material film are alternately stacked. In the composite domain dielectric film 182, the plurality of first dielectric regions DR1 facing the plurality of gate lines 130 may have different stack structures and different widths from the plurality of second dielectric regions DR2 facing the plurality of insulating patterns 132. Accordingly, the composite domain dielectric film 182 may have improved spontaneous polarization characteristics and an increased relative dielectric constant. Even when the composite domain dielectric film 182 is thinned with an increase in the integration density of the semiconductor device 100A, the composite domain dielectric film 182 may maintain ferroelectric characteristics and have improved data retention characteristics. Furthermore, undesired coupling effects between the plurality of gate lines 130 may be reduced. Therefore, reliability of the semiconductor device 100A may improve.

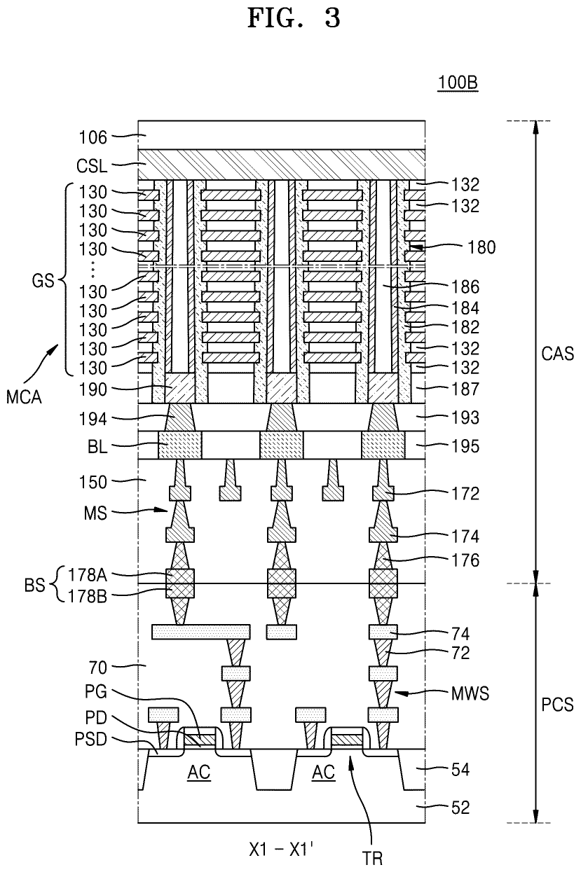

FIG. 3 is a cross-sectional view of a semiconductor device 100B according to an example embodiment. In FIG. 3, the same reference numerals are used to denote the same elements as in FIGS. 2A to 2D, and detailed descriptions thereof are omitted.

Referring to FIG. 3, the semiconductor device 100B may include a cell array structure CAS and a peripheral circuit structure PCS, which overlap each other in a vertical direction (Z direction). The cell array structure CAS may include a memory cell region MEC in which a memory cell array MCA is located.

In some example embodiments, the semiconductor device 100B may have a chip-to-chip (C2C) structure. The C2C structure may refer to a structure obtained by connecting the cell array structure CAS and the peripheral circuit structure PCS to each other by using a bonding method after forming the cell array structure CAS on a first wafer and forming the peripheral circuit structure PCS on a second wafer that is different from the first wafer. For example, the bonding method may refer to a method of electrically connecting a first bonding metal pad 178A formed on an uppermost metal layer of the cell array structure CAS and a second bonding metal pad 178B formed on an uppermost metal layer of the peripheral circuit structure PCS. In some example embodiments, when the first bonding metal pad 178A and the second bonding metal pad 178B include copper (Cu), the bonding method may be a Cu—Cu bonding method. In other example embodiments, each of the first bonding metal pad 178A and the second bonding metal pad 178B may include aluminum (Al) or tungsten (W).

A gate stack GS including a plurality of gate lines 130 included in the memory cell array MCA may be between a common source line CSL and the peripheral circuit structure PCS.

The peripheral circuit structure PCS may include a substrate 52, a plurality of circuits on the substrate 52, and a multilayered wiring structure MWS configured to connect the plurality of circuits to each other or a multilayered wiring structure MWS configured to connect the plurality of circuits to components in the memory cell area MEC of the cell array structure CAS.

The substrate 52 may include a semiconductor substrate. For example, the substrate 52 may include Si, Ge, or SiGe. An active region AC may be defined by a device isolation film 54 in the substrate 52. A plurality of transistors TR constituting the plurality of circuits may be formed on the active region AC. Each of the plurality of transistors TR may include a gate dielectric film PD and a gate PG, which are sequentially stacked on the substrate 52, a plurality of ion implantation regions PSD, which are formed on both sides of the gate PG in the active region AC. Each of the plurality of ion implantation regions PSD may constitute a source region or a drain region of the transistor TR.

The multilayered wiring structure MWS included in the peripheral circuit structure PCS may include a plurality of contact plugs 72 and a plurality of conductive lines 74. At least some of the plurality of conductive lines 74 may be electrically connectable to the transistor TR. The plurality of contact plugs 72 may connect the plurality of transistors TR to one or more conductive lines selected from the plurality of conductive lines 74. The plurality of transistors TR and the multilayered wiring structure MWS, which are in the peripheral circuit structure PCS, may be covered by an interlayer insulating film 70. The interlayer insulating film 70 may include a silicon oxide film, a silicon nitride film, a SiON film, a SiOCN film, or a combination thereof.

The plurality of circuits included in the peripheral circuit structure PCS may include various circuits included in the peripheral circuit 30 described with reference to FIG. 1. In some example embodiments, the peripheral circuit structure PCS may further include unit elements, such as resistors and capacitors. In the peripheral circuit structure PCS, the plurality of transistors TR, the plurality of contact plugs 72, and the plurality of conductive lines 74 may constitute the plurality of circuits. Each of the plurality of transistors TR may be electrically connected to the memory cell region MEC through a plurality of multilayered wiring structures MWS. The common source line CSL included in the cell array structure CAS may be apart from the peripheral circuit structure PCS with the memory cell region MEC therebetween in the vertical direction (Z direction).

Each of the plurality of bit lines BL may be connected to a wiring structure MS. The wiring structure MS may include a first upper wiring layer 172, a second upper wiring layer 174, and a third upper wiring layer 176. Each of the first upper wiring layer 172, the second upper wiring layer 174, and the third upper wiring layer 176 may include tungsten, titanium, tantalum, copper, aluminum, titanium nitride, tantalum nitride, tungsten nitride, or a combination thereof.

A plurality of first bonding metal pads 178A may be on a top surface of the cell array structure CAS, which is adjacent to the peripheral circuit structure PCS. The plurality of bit lines BL may be connected to the plurality of first bonding metal pads 178A through the wiring structure MS. In the cell array structure CAS, each of the wiring structure MS and the plurality of first bonding metal pads 178A may be covered by an interlayer insulating film 150. The interlayer insulating film 150 may include a silicon oxide film, a silicon nitride film, or a combination thereof.

The peripheral circuit structure PCS may be apart from the plurality of channel structures 180 with the plurality of bit lines BL therebetween. The peripheral circuit structure PCS may include a plurality of second bonding metal pads 178B on the multilayered wiring structure MWS. The plurality of second bonding metal pads 178B may be connected to a plurality of circuits included in the peripheral circuit structure PCS. In the peripheral circuit structure PCS, the interlayer insulating film 70 may cover the plurality of transistors TR, the plurality of conductive plugs 72, the plurality of conductive lines 74, and the plurality of second bonding metal pads 178B.

The plurality of second bonding metal pads 178B may be bonded to the plurality of first bonding metal pads 178A included in the cell array structure CAS and be electrically connected to the plurality of first bonding metal pads 178A. The plurality of first bonding metal pads 178A and the plurality of second bonding metal pads 178B may constitute a plurality of bonding structures BS. The plurality of bit lines BL may be connected to at least one circuit selected from the plurality of circuits included in the peripheral circuit structure PCS through the bonding structure BS including the first bonding metal pad 178A and the second bonding metal pad 178B.

In some example embodiments, each of the plurality of conductive plugs 72 and the plurality of conductive lines 74, which are in the peripheral circuit structure PCS, may include tungsten, aluminum, copper, or a combination thereof, without being limited thereto. The device isolation film 54 may include a silicon oxide film, a silicon nitride film, or a combination thereof. The interlayer insulating film 70 may include a silicon oxide film, a silicon nitride film, or a combination thereof. The plurality of first bonding metal pads 178A and the plurality of second bonding metal pads 178B, which constitute the bonding structure BS, may each include copper, aluminum, or tungsten.

In the cell array structure CAS, the common source line CSL may be covered by an insulating film 106. The insulating film 106 may include a silicon oxide film. Although not shown, the insulating film 106 may be covered by a protective film. The protective film may include a polyimide-based material film, such as a photosensitive polyimide (PSPI) film, without being limited thereto.

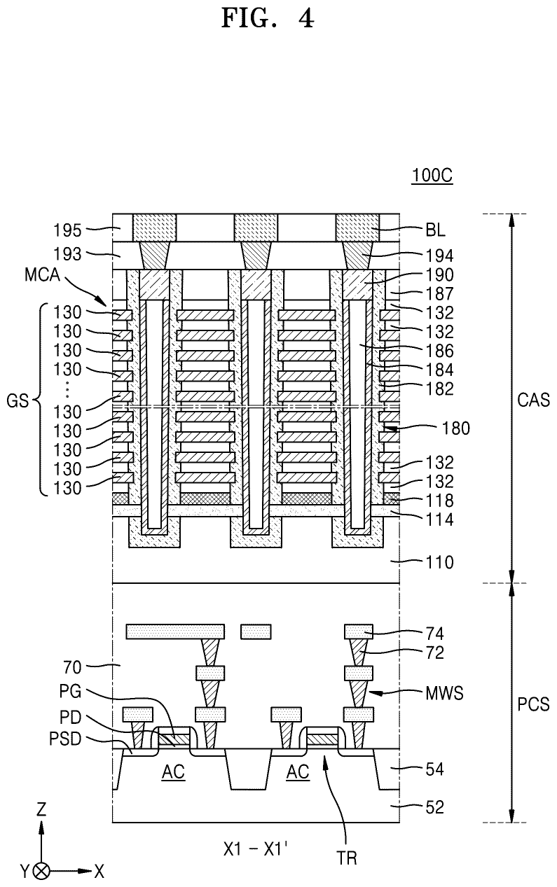

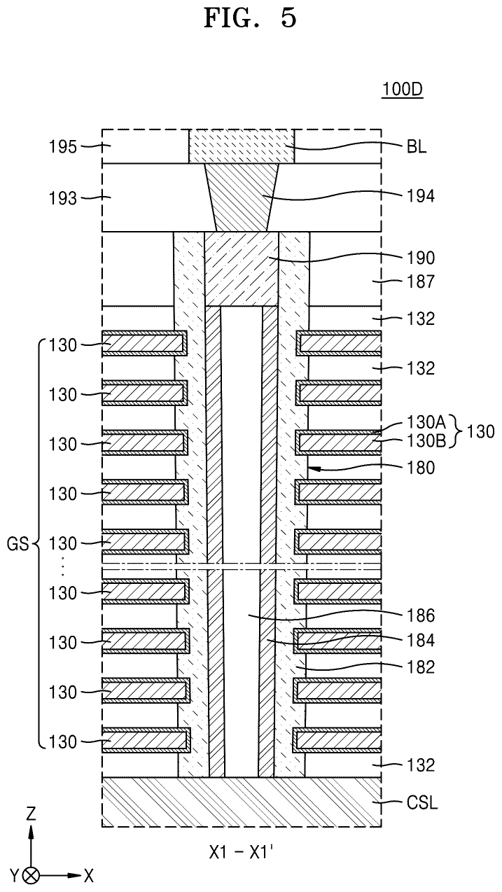

FIG. 4 is a cross-sectional view of a semiconductor device 100C according to an example embodiment. In FIG. 4, the same reference numerals are used to denote the same elements as in FIGS. 1 to 3, and detailed descriptions thereof are omitted.

Referring to FIG. 4, the semiconductor device 100C may have the same or substantially similar configuration as the semiconductor device 100B described with reference to FIG. 3. However, a cell array structure CAS of the semiconductor device 100C may include a cell structure 110 on a peripheral circuit structure PCS and a gate stack GS on the cell substrate 110.

In the cell array structure CAS, a first conductive plate 114 and a second conductive plate 118 may be sequentially arranged on the cell substrate 110, and the gate stack GS including a plurality of gate lines 130 may be on the second conductive plate 118.

The cell substrate 110, the first conductive plate 114, and the second conductive plate 118 may function as the common source line (refer to CSL in FIG. 1) configured to supply current vertical memory cells included in the cell array structure CAS.

In some example embodiments, the cell substrate 110 may include a semiconductor material, such as doped polysilicon. Each of the first conductive plate 114 and the second conductive plate 118 may include a doped polysilicon film, a metal film, or a combination thereof. The metal film may include tungsten (W), without being limited thereto. An insulating pattern 132 may be between the second conductive plate 118 and the plurality of gate lines 130 and between two adjacent ones of the plurality of gate lines 130.

In the semiconductor device 100C, the peripheral circuit structure PCS may be apart from the bit line BL with the plurality of gate lines 130 therebetween. The cell substrate 110 may be between the peripheral circuit structure PCS and the first conductive plate 114. The composite domain dielectric film 182 of each of the plurality of channel structures 180 may pass through the second conductive plate 118 in a vertical direction (Z direction) and pass through a portion of the cell substrate 110 in the vertical direction (Z direction) and extend long in the vertical direction (Z direction). The channel film 184 and the insulating plug 186 of each of the plurality of channel structures 180 may pass through the first conductive plate 114 and the second conductive plate 118 in the vertical direction (Z direction) and pass through a portion of the cell substrate 110 in the vertical direction (Z direction) and extend long in the vertical direction (Z direction). The first conductive plate 114 may pass through the composite domain dielectric film 182 in a lateral direction and contact a sidewall of the channel film 184.

FIG. 5 is a cross-sectional view of a semiconductor device 100D according to an example embodiment. FIG. 5 illustrates an enlarged configuration of a region of the semiconductor device 100D, which corresponds to region “EX1A” of FIG. 2B. In FIG. 5, the same reference numerals are used to denote the same elements as in FIGS. 2A to 2D, and detailed descriptions thereof are omitted.

Referring to FIG. 5, the semiconductor device 100D may have the same or substantially similar configuration as the semiconductor device 100A described with reference to FIGS. 2A to 2D. However, in the semiconductor device 100D, each of the plurality of gate lines 130 may include a conductive barrier film 130A and a metal film 130B surrounded by the conductive barrier film 130A. In some example embodiments, the conductive barrier film 130A may include a titanium nitride (TiN) film or a tantalum nitride (TaN) film, and the metal film 130B may include a tungsten (W) film, a molybdenum (Mo) film, or a ruthenium (Ru) film, without being limited thereto.

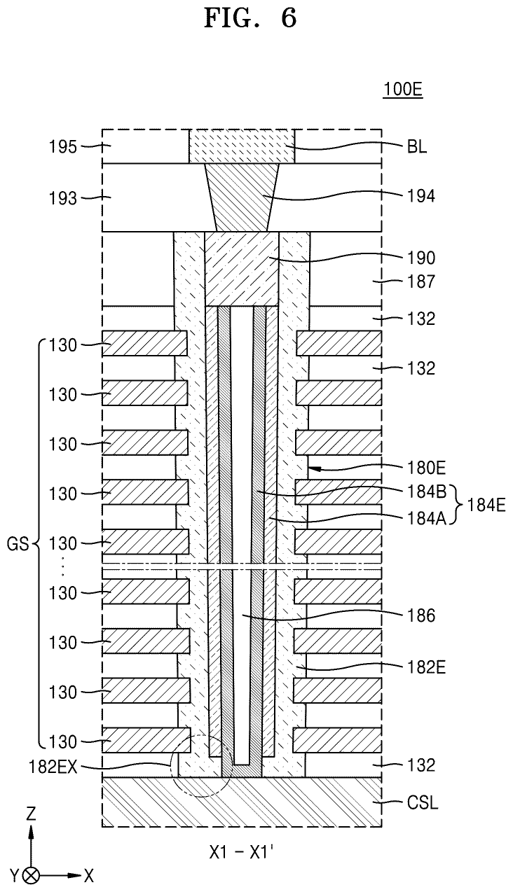

FIG. 6 is a cross-sectional view of a semiconductor device 100E according to an example embodiment. FIG. 6 illustrates an enlarged configuration of a region of the semiconductor device 100E, which corresponds to region “EX1A” of FIG. 2B. In FIG. 6, the same reference numerals are used to denote the same elements as in FIGS. 2A to 2D, and detailed descriptions thereof are omitted.

Referring to FIG. 6, the semiconductor device 100E may have the same or substantially similar configuration as the semiconductor device 100A described with reference to FIGS. 2A to 2D. The semiconductor device 100E may include a channel structure 180E. The channel structure 180E may have the same or substantially similar configuration as the channel structure 180 described with reference to FIGS. 2A to 2D. However, the channel structure 180E may include a composite domain dielectric film 182E having an L-shaped sectional structure and a channel film 184E having a plurality of channel film structures.

The channel film 184E may include a first channel film 184A and a second channel film 184B, which extend parallel to each other in a vertical direction (Z direction). The first channel film 184A and the second channel film 184B, which are in the channel film 184E, may be in contact with each other. The first channel film 184A may have a surface in contact with the composite domain dielectric film 182E and a surface in contact with the second channel film 184B. The second channel film 184B may be apart from the composite domain dielectric film 182E with the first channel film 184A therebetween in a lateral direction.

In the vertical direction (Z direction), a length of the first channel film 184A may be different from a length of the second channel film 184B. From among the first channel film 184A and the second channel film 184B, the first channel film 184 may face a plurality of gate lines 130 with the composite domain dielectric film 182E therebetween and contact the composite domain dielectric film 182E, and a length of the first channel film 184 in the vertical direction (Z direction) may be less than a length of the second channel film 184B in the vertical direction (Z direction).

The first channel film 184A and the second channel film 184B may include different materials, which are selected from polysilicon, an oxide semiconductor, a 2D semiconductor material, and a combination thereof. Details of the oxide semiconductor and the 2D semiconductor material are the same as those described with reference to FIGS. 2A to 2D.

In some example embodiments, a selected one of the first channel film 184A and the second channel film 184B may include a p-type oxide semiconductor, and the other selected one of the first channel film 184A and the second channel film 184B may include an n-type oxide semiconductor. Details of the p-type an oxide semiconductor and the n-type an oxide semiconductor are the same as those described with reference to FIGS. 2A to 2D.

Similar to the composite domain dielectric film 182 described with reference to FIGS. 2A to 2D, the composite domain dielectric film 182E may include a vertical extension, which faces a stack structure including the plurality of gate lines 130 and a plurality of insulating patterns 132 and extends long in a vertical direction (Z direction). Unlike the composite domain dielectric film 182 described with reference to FIGS. 2A to 2D, the composite domain dielectric film 182E may further include a horizontal extension covering a bottom surface of the first channel film 184A. One end portion of the composite domain dielectric film 182E, which is adjacent to a common source line CSL, may include an L-shaped portion 182EX surrounding a partial region of the channel film 184E, which is adjacent to the common source line CSL. The composite domain dielectric film 182E may have the same or substantially similar configuration as the composite domain dielectric film 182 described with reference to FIGS. 2A to 2D.

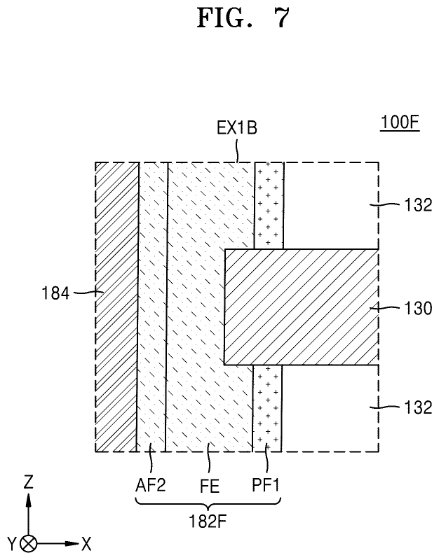

FIG. 7 is a cross-sectional view of a semiconductor device 100F according to an example embodiment. FIG. 7 illustrates an enlarged configuration of a region of the semiconductor device 100F, which corresponds to region “EX1B” of FIG. 2B. In FIG. 7, the same reference numerals are used to denote the same elements as in FIGS. 2A to 2D, and detailed descriptions thereof are omitted.

Referring to FIG. 7, the semiconductor device 100F may have the same or substantially similar configuration as the semiconductor device 100A described with reference to FIGS. 2A to 2D. However, a composite domain dielectric film 182F of the semiconductor device 100F may include a main domain FE and a plurality of first sub-domains PF1 and a second sub-domain AF2, which are apart from each other with the main domain FE therebetween in a lateral direction. Details of the plurality of first sub-domains PF1 may be the same as or substantially similar to details of the plurality of first sub-domains AF1 described with reference to FIGS. 2A to 2D. However, the plurality of first sub-domains PF1 may include a paraelectric material. In the composite domain dielectric film 182F of the semiconductor device 100F, the main domain FE may include a ferroelectric material, and the second sub-domain AF2 may include an anti-ferroelectric material. Details of the ferroelectric material, the paraelectric material, and the anti-ferroelectric material may be the same as or substantially similar to those described with reference to FIGS. 2A to 2D.

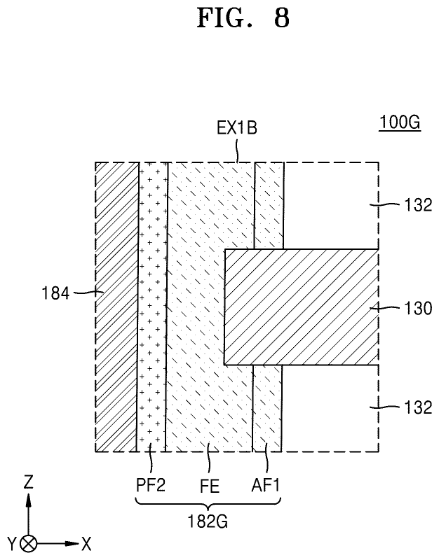

FIG. 8 is a cross-sectional view of a semiconductor device 100G according to an example embodiment. FIG. 8 illustrates an enlarged configuration of a region of the semiconductor device 100G, which corresponds to region “EX1B” of FIG. 2B. In FIG. 8, the same reference numerals are used to denote the same elements as in FIGS. 2A to 2D, and detailed descriptions thereof are omitted.

Referring to FIG. 8, the semiconductor device 100G may have the same or substantially similar configuration as the semiconductor device 100A described with reference to FIGS. 2A to 2D. However, a composite domain dielectric film 182G of the semiconductor device 100G may include a main domain FE and a plurality of first sub-domains AF1 and a second sub-domain PF2, which are apart from each other with the main domain FE therebetween in a lateral direction. Details of the second sub-domain PF2 may be the same as or substantially similar to details of the second sub-domain AF2 described with reference to FIGS. 2A to 2D. However, the second sub-domain PF2 may include a paraelectric material. In the composite domain dielectric film 182G of the semiconductor device 100G, the main domain FE may include a ferroelectric material, and the plurality of first sub-domains AF1 may include an anti-ferroelectric material. Details of the ferroelectric material, the paraelectric material, and the anti-ferroelectric material are the same as those described with reference to FIGS. 2A to 2D.

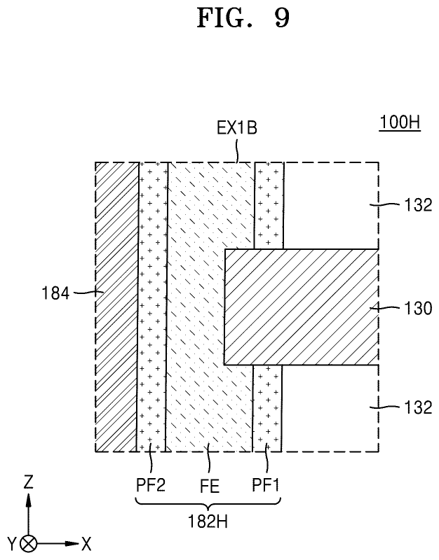

FIG. 9 is a cross-sectional view of a semiconductor device 100H according to an example embodiment. FIG. 9 illustrates an enlarged configuration of a region of the semiconductor device 100G, which corresponds to region “EX1B” of FIG. 2B. In FIG. 9, the same reference numerals are used to denote the same elements as in FIGS. 2A to 2D, and detailed descriptions thereof are omitted.

Referring to FIG. 9, the semiconductor device 100H may have the same or substantially similar configuration as the semiconductor device 100A described with reference to FIGS. 2A to 2D. However, a composite domain dielectric film 182H of the semiconductor device 100H may include a main domain FE and a plurality of first sub-domains PF1 and a second sub-domain PF2, which are apart from each other with the main domain FE therebetween in a lateral direction. Details of the plurality of first sub-domains PF1 and the second sub-domain PF2 may be the same as or substantially similar to those of the plurality of first sub-domains AF1 and the second sub-domain AF2 described with reference to FIGS. 2A to 2D. However, each of the plurality of first sub-domains PF1 and the second sub-domain AF2 may include a paraelectric material. In the composite domain dielectric film 182G of the semiconductor device 100H, the main domain FE may include a ferroelectric material. Details of the ferroelectric material and the paraelectric material are the same as those described with reference to FIGS. 2A to 2D.

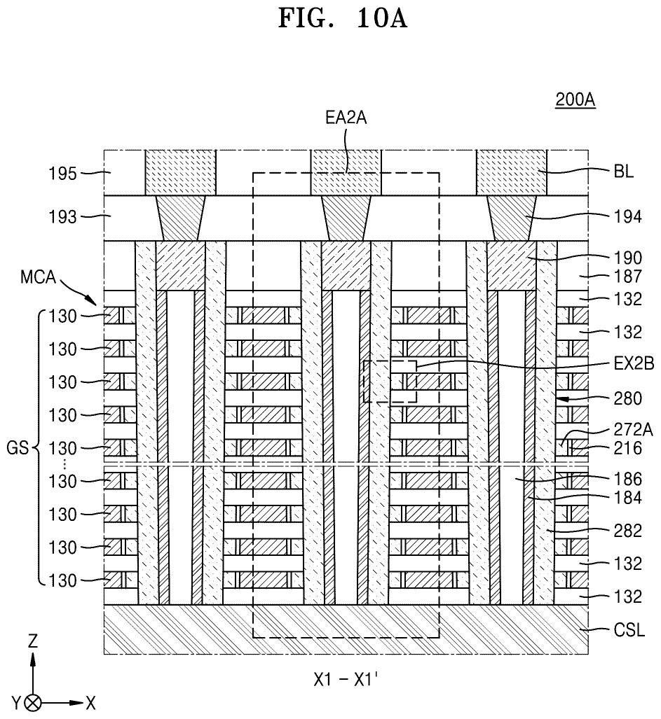

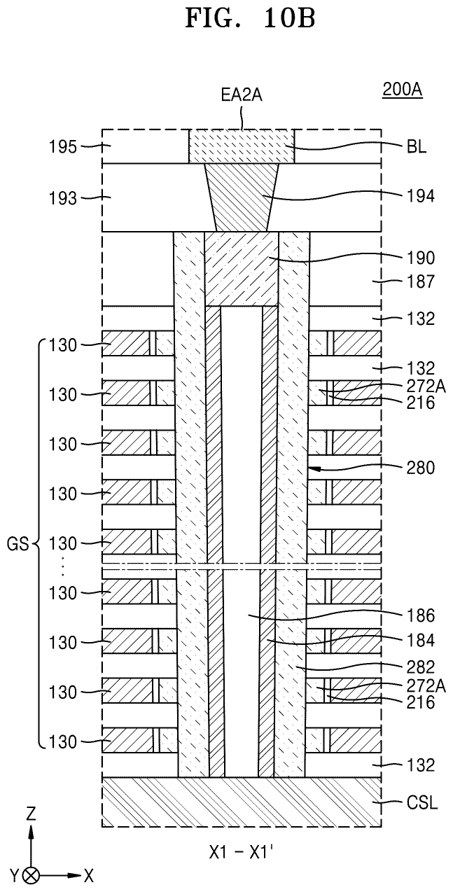

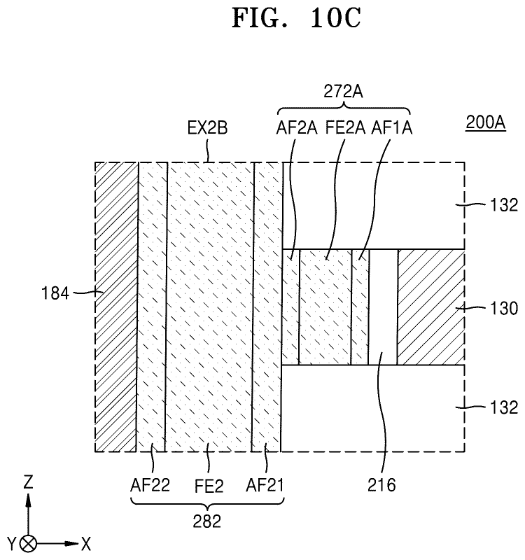

FIGS. 10A to 10C are cross-sectional views of a semiconductor device 200A according to an example embodiment. FIG. 10A is a cross-sectional view of some regions of a memory cell array MCA of the semiconductor device 200A. FIG. 10B is an enlarged cross-sectional view of region “EX2A” of FIG. 10A. FIG. 10C is an enlarged cross-sectional view of region “EX2B” of FIG. 10A. In FIGS. 10A to 10C, the same reference numerals are used to denote the same elements as in FIGS. 2A to 2D, and detailed descriptions thereof are omitted.

The semiconductor device 200A shown in FIGS. 10A to 10C may have a planar configuration substantially similar to that of the cell array structure CAS shown in FIG. 2A. At least one memory cell block BLK selected from the plurality of memory cell blocks BLK1, BLK2, . . . , and BLKp shown in FIG. 1 may have the same configuration as in the semiconductor device 200A described with reference to FIGS. 10A to 10C.

Referring to FIGS. 10A to 10C, the semiconductor device 200A may have the same or substantially similar configuration as the semiconductor device 100A described with reference to FIGS. 2A to 2D. The semiconductor device 200A may include a plurality of channel structures 280. The plurality of channel structures 280 may have the same or substantially similar configuration as the plurality of channel structures 180 described with reference to FIGS. 2A to 2D. However, each of the plurality of channel structures 280 may include a plurality of local composite dielectric films 272A, a composite domain dielectric film 282, a channel film 184, and an insulating plug 186.

The plurality of local composite dielectric films 272A may be apart from each other in a vertical direction (Z direction). The local composite dielectric film 272A, the composite domain dielectric film 282, the channel film 184, and the insulating plug 186 may be sequentially stacked from the plurality of gate lines 130 toward the center of the channel structure 280.

Each of the plurality of local composite dielectric films 272A may be between the composite domain dielectric film 282 and a corresponding one of the plurality of gate lines 130. Each of the plurality of local composite dielectric films 272A may include a first domain AF1A, a second domain FE2A, and a third domain AF2A, which are sequentially stacked from a selected or corresponding one of the plurality of gate lines 130 toward the composite domain dielectric film 282. Each of the first domain AF1A and the third domain AF2A may include at least one material selected from an anti-ferroelectric material and a paraelectric material, and the second domain FE2A may include a ferroelectric material. Details of the anti-ferroelectric material, the paraelectric material, and the ferroelectric material are the same as those described with reference to FIGS. 2A to 2D. In embodiments, in a lateral direction (e.g., an X direction of FIGS. 10A to 10C), a width of the second domain FE2A may be greater than each of the first domain AF1A and the third domain AF2A.

The composite domain dielectric film 282 may extend long in the vertical direction (Z direction) to be between the channel film 184 and the plurality of gate lines 130 and between the channel film 184 and the plurality of local composite dielectric films 272A. One end portion of the composite domain dielectric film 182 may be in contact with the conductive pad 190, and another end portion of the composite domain dielectric film 182 may be in contact with a common source line CSL. As used herein, the one end portion of the composite domain dielectric film 282, which is in contact with the conductive pad 190, may be referred to as a first end portion, and the other end portion of the composite domain dielectric film 282, which is in contact with the common source line CSL, may be referred to as a second end portion. In the lateral direction, a width of the composite domain dielectric film 282 may be constant in the vertical direction (Z direction).

As shown in FIG. 10C, the composite domain dielectric film 282 may include a main domain FE2 and at least one sub-domain in contact with the main domain FE2. The at least one sub-domain may include a first sub-domain AF21 and a second sub-domain AF22, which are apart from each other with the main domain FE2 therebetween in the lateral direction. Each of the main domain FE2, the first sub-domain AF21, and the second sub-domain AF22, which are in the composite domain dielectric 282, may extend long in the vertical direction (Z direction) to be between a plurality of insulating patterns 132 and the channel film 184 and between the local composite dielectric film 272A the channel film 184. Details of respective constituent materials and widths of the main domain FE2, the first sub-domain AF21, and the second sub-domain AF22 that are in the composite domain dielectric film 282 may be the same as or substantially similar to those of the main domain FE, the plurality of first sub-domains AF1, and the second sub-domain AF2 that are in the composite domain dielectric film 182 as described with reference to FIGS. 2A to 2D.

A plurality of dielectric films 216 may be between the plurality of gate lines 130 and the plurality of local composite dielectric films 272A, respectively. In some example embodiments, the plurality of dielectric films 216 may include a silicon oxide film, without being limited thereto.

In the semiconductor device 200A shown in FIGS. 10A to 10C, the plurality of channel structures 280 may include the local composite dielectric film 272A and the composite domain dielectric film 282. Thus, a first dielectric film structure including the local composite dielectric film 272A and the composite domain dielectric film 282 may be between the channel film 184 and the gate line 130, and a second dielectric film structure including only the composite domain dielectric film 282 may be between the channel film 184 and the insulating pattern 132. Accordingly, a thickness (or a lateral width) of the first dielectric film structure between the channel film 184 and the gate line 130 may be greater than a thickness (or a lateral width) of the second dielectric film structure between the channel film 184 and the insulating pattern 132. In some example embodiments, a thickness of the first dielectric film structure may be selected in a range of about 0.1 nm to about 20 nm, and a thickness of the second dielectric film structure may be selected in a range of about 0.2 nm to about 15 nm, without being limited thereto.

Because the first dielectric film structure in channel regions between the channel film 184 and the plurality of gate lines 130 has a greater thickness than the second dielectric film structure in other regions adjacent to the first dielectric film structure (e.g., regions between the channel film 184 and the plurality of insulating patterns 132), a coercive field Ec of each of the adjacent regions may become higher than a coercive field Ec of each of the channel regions. The coercive field Ec may be defined as an electric field in which polarization becomes zero (0) in a polarization-electric field (P-E) hysteresis loop. That is, the coercive field Ec may refer to a size of a critical electric field that may change a direction of polarization. Because the coercive field Ec of each of the adjacent regions may become higher than the coercive field Ec of each of the channel regions as described above, even when a distance between adjacent cells in the vertical direction (Z direction) is relatively small in the composite domain dielectric film 282, cell interference between the adjacent cells may be suppressed.

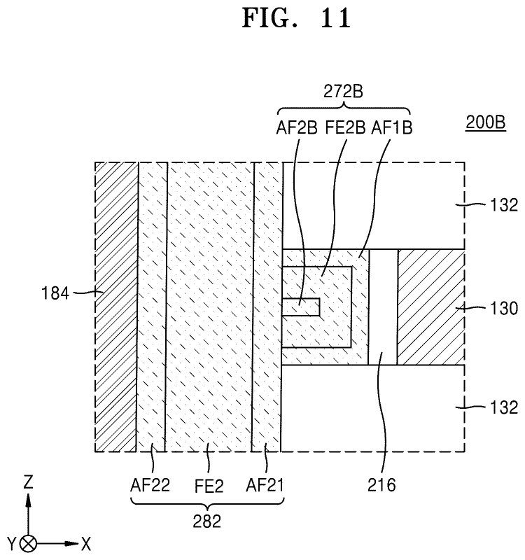

FIG. 11 is a cross-sectional view of a semiconductor device 200B according to an example embodiment. FIG. 11 illustrates an enlarged configuration of a region of the semiconductor device 200B, which corresponds to region “EX2B” of FIG. 10A. In FIG. 11, the same reference numerals are used to denote the same elements as in FIGS. 2A to 10C, and detailed descriptions thereof are omitted.

Referring to FIG. 11, the semiconductor device 200B may have the same or substantially similar configuration as the semiconductor device 200A described with reference to FIGS. 10A to 10C. However, a local composite dielectric film 272B of the semiconductor device 200B may include a first domain AF1B, a second domain FE2B, and a third domain AF2B, which are sequentially stacked from the gate line 130 toward a composite domain dielectric film 282. Each of the first domain AF1B and the third domain AF2B may include at least one selected from an anti-ferroelectric material and a paraelectric material, and the second domain FE2B may include a ferroelectric material. Details of the anti-ferroelectric material, the paraelectric material, and the ferroelectric material are the same as those described with reference to FIGS. 2A to 2D.

In the local composite dielectric film 272B, each of the first domain AF1B and the second domain FE2B may have a C-shaped cross-sectional shape. Each of the first domain AF1B, the second domain FE2B, and the third domain AF2B may have a surface in contact with the first sub-domain AF21 included in the composite domain dielectric film 282.

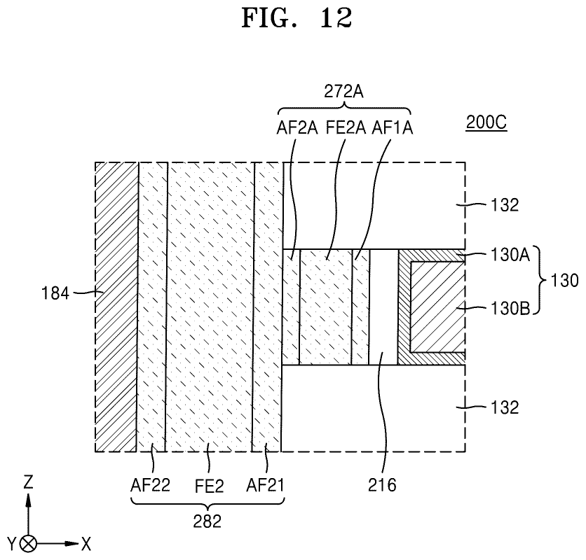

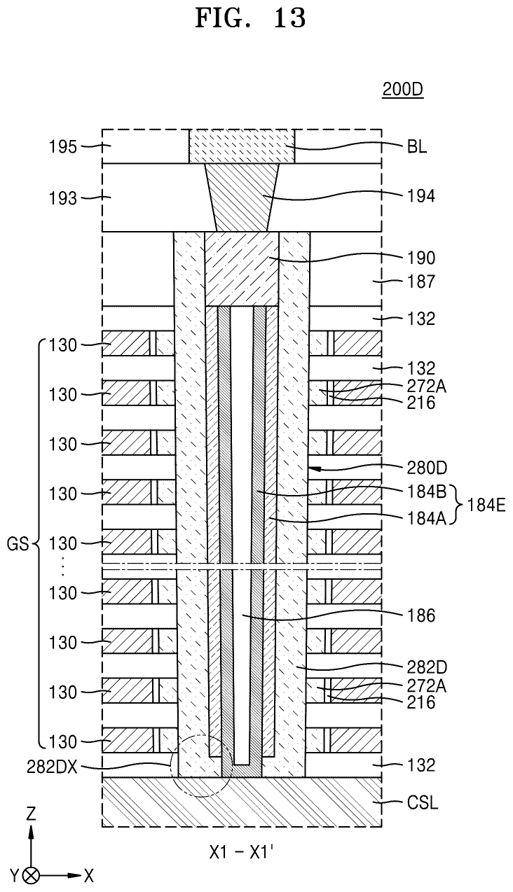

FIG. 12 is a cross-sectional view of a semiconductor device 200C according to an example embodiment. FIG. 12 illustrates an enlarged configuration of a region of the semiconductor device 200C, which corresponds to region “EX2B” of FIG. 10A. In FIG. 12, the same reference numerals are used to denote the same elements as in FIGS. 2A to 10C, and detailed descriptions thereof are omitted.

Referring to FIG. 12, the semiconductor device 200C may have the same or substantially similar configuration as the semiconductor device 200A described with reference to FIGS. 10A to 10C. However, in the semiconductor device 200C, each of a plurality of gate lines 130 may include a conductive barrier film 130A and a metal film 130B surrounded by the conductive barrier film 130A. In some example embodiments, the conductive barrier film 130A may include a TiN film or a TaN film, and the metal film 130B may include a W film, a Mo film, or a Ru film, without being limited thereto.

FIG. 13 is a cross-sectional view of a semiconductor device 200D according to an example embodiment. FIG. 13 illustrates an enlarged configuration of a region of the semiconductor device 200D, which corresponds to region “EX2A” of FIG. 10A. In FIG. 13, the same reference numerals are used to denote the same elements as in FIGS. 2A to 10C, and detailed descriptions thereof are omitted.

Referring to FIG. 13, the semiconductor device 200D may have the same or substantially similar configuration as the semiconductor device 200A described with reference to FIGS. 10A to 10C. The semiconductor device 200D may include a channel structure 280D. The channel structure 280D may have the same or substantially similar configuration as the channel structure 280 described with reference to FIGS. 10A to 10C. However, the channel structure 280D may include a composite domain dielectric film 282D having an L-shaped sectional structure and a channel film 184E having a plurality of channel film structures. The channel film 184E may include a first channel film 184A and a second channel film 184B, which extend parallel to each other in a vertical direction (Z direction). Details of the channel film 184E including the first channel film 184A and the second channel film 184B are the same as those described with reference to FIG. 6.

Similar to the composite domain dielectric film 282 described with reference to FIGS. 10A to 10C, the composite domain dielectric film 282D may include a vertical extension, which faces a stack structure including a plurality of gate lines 130 and a plurality of insulating patterns 132 and extends long in the vertical direction (Z direction). Unlike the composite domain dielectric film 282 described with reference to FIGS. 10A to 10C, the composite domain dielectric film 282D may further include a horizontal extension covering a bottom surface of the first channel film 184A. One end portion of the composite domain dielectric film 282D, which is adjacent to a common source line CSL, may include an L-shaped portion 282DX surrounding a partial region of the channel film 184E, which is adjacent to the common source line CSL. Details of the composite domain dielectric film 282D may be the same as or substantially similar to those of the composite domain dielectric film 282 described with reference to FIGS. 10A to 10C.

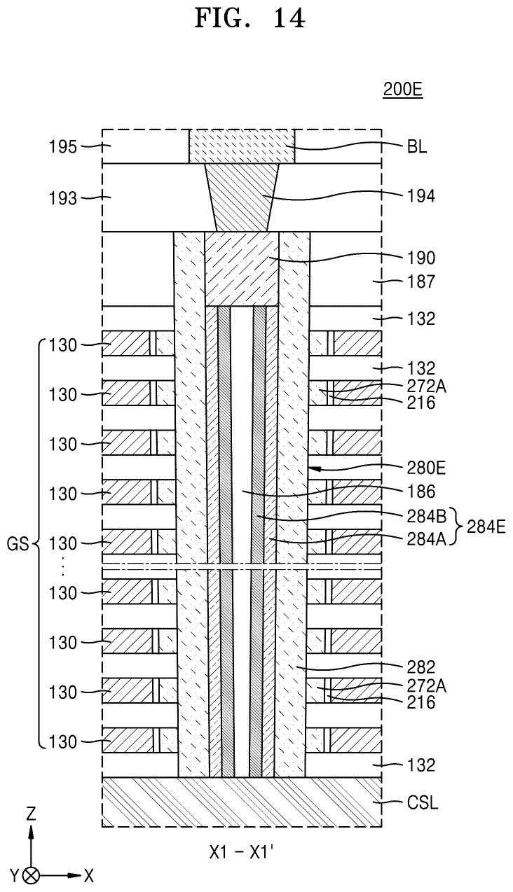

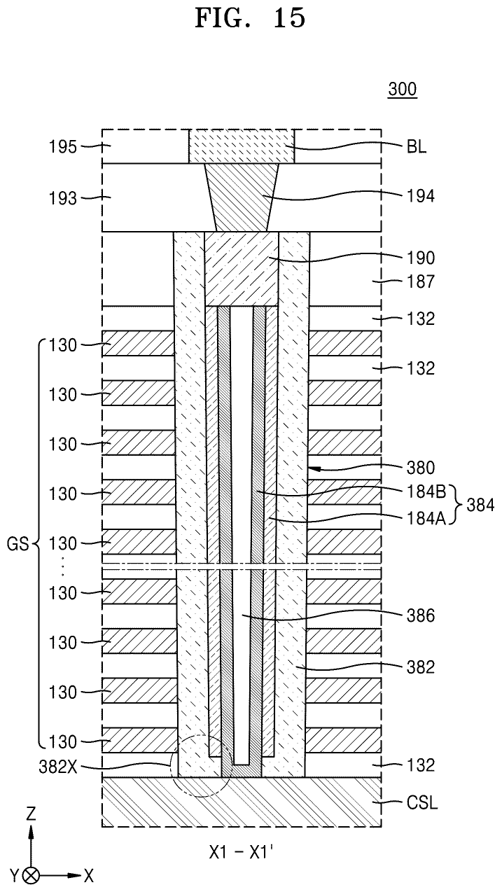

FIG. 14 is a cross-sectional view of a semiconductor device 200E according to embodiments. FIG. 14 illustrates an enlarged configuration of a region of the semiconductor device 200E, which corresponds to region “EX2A” of FIG. 10A. In FIG. 14, the same reference numerals are used to denote the same elements as in FIGS. 2A to 10C, and detailed descriptions thereof are omitted.

Referring to FIG. 14, the semiconductor device 200E may have the same or substantially similar configuration as the semiconductor device 200A described with reference to FIGS. 10A to 10C. The semiconductor device 200E may include a channel structure 280E. The channel structure 280E may have the same or substantially similar configuration as the channel structure 280 described with reference to FIGS. 10A to 10C. However, a channel film 284E of the channel structure 280E may include a first channel film 284A and a second channel film 284B, which extend parallel to each other in a vertical direction (Z direction).

The first channel film 284A and the second channel film 284B, which are in the channel film 284E, may be in contact with each other. The first channel film 284A may have a surface in contact with a composite domain dielectric film 282 and a surface in contact with the second channel film 284B. The second channel film 284B may be apart from the composite domain dielectric film 282 with the first channel film 284A therebetween in a lateral direction.

The first channel film 284A and the second channel film 284B may include different materials, which are selected from polysilicon, an oxide semiconductor, a 2D semiconductor material, and a combination thereof. Details of the oxide semiconductor and the 2D semiconductor material are the same as those described with reference to FIGS. 2A to 2D.

In some example embodiments, a selected one of the first channel film 284A and the second channel film 284B may include a p-type an oxide semiconductor, and the other selected one of the first channel film 284A and the second channel film 284B may include an n-type an oxide semiconductor. Details of the p-type an oxide semiconductor and the n-type an oxide semiconductor are the same as those described with reference to FIGS. 2A to 2D.

FIG. 15 is a cross-sectional view of a semiconductor device 300 according to an example embodiment. FIG. 15 illustrates an enlarged configuration of a region of the semiconductor device 300, which corresponds to region “EX1A” of FIG. 2B. In FIG. 15, the same reference numerals are used to denote the same elements as in FIGS. 2A to 2D, and detailed descriptions thereof are omitted.

Referring to FIG. 15, the semiconductor device 300 may have the same or substantially similar configuration as the semiconductor device 100A described with reference to FIGS. 2A to 2D. The semiconductor device 300 may include a channel structure 380. The channel structure 380 may have the same or substantially similar configuration as the channel structure 180 described with reference to FIGS. 2A to 2D. However, the channel structure 380 may include a composite domain dielectric film 382, a channel film 384, and an insulating plug 386, which are sequentially stacked from a plurality of gate lines 130 toward the center of the channel structure 380.

The composite domain dielectric film 382 may have the same or substantially similar configuration as the composite domain dielectric film 182 described with reference to FIGS. 2A to 2D. However, the composite domain dielectric film 382 may have a constant width in a vertical direction (Z direction). Portions of the composite domain dielectric film 382, which face the plurality of gate lines 130, may have the same stack structures and the same lateral widths as portions of the composite domain dielectric film 382, which face a plurality of insulating patterns 132. Similar to the composite domain dielectric film 282 described with reference to FIG. 10C, the composite domain dielectric film 382 may include a main domain FE2 and a first sub-domain AF21 and a second sub-domain AF22, which are apart from each other with the main domain FE2 therebetween in the lateral direction. Details of the main domain FE2, the first sub-domain AF21, and the second sub-domain AF22 may be the same as those described with reference to FIG. 10C.

The channel film 384 may include a first channel film 184A and a second channel film 184B, which extend parallel to each other in the vertical direction (Z direction). Details of the first channel film 184A and the second channel film 184B are the same as those described with reference to FIG. 6.

The composite domain dielectric film 382 of the channel structure 380 may have an L-shaped sectional structure. Similar to the composite domain dielectric film 182 described with reference to FIGS. 2A to 2D, the composite domain dielectric film 382 may include a vertical extension, which faces a stack structure including the plurality of gate lines 130 and the plurality of insulating patterns 132 and extends long in the vertical direction (Z direction). Unlike the composite domain dielectric film 182 described with reference to FIGS. 2A to 2D, the composite domain dielectric film 382 may further include a horizontal extension covering a bottom surface of the channel film 384. One end portion of the composite domain dielectric film 382, which is adjacent to a common source line CSL, may include an L-shaped portion 382X surrounding a partial region of the channel film 384, which is adjacent to the common source line CSL. Details of the composite domain dielectric film 382 may be the same as or substantially similar to those of the composite domain dielectric film 182 described with reference to FIGS. 2A to 2D.

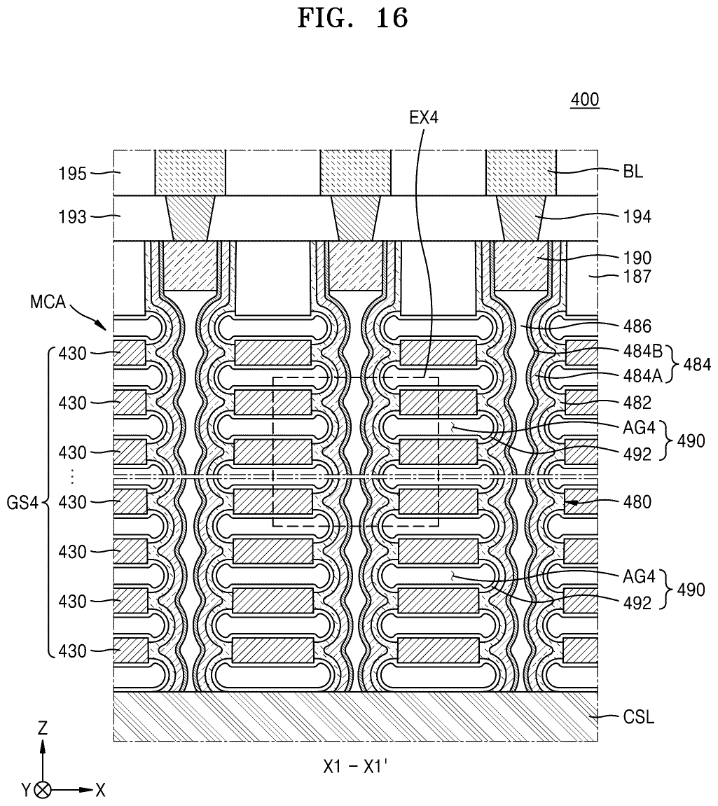

FIG. 16 is a cross-sectional view of a semiconductor device 400 according to an example embodiment. FIG. 16 illustrates a partial cross-sectional configuration of a region corresponding to a cross-section taken along line X1-X1′ of FIG. 2A in a memory cell array MCA of the semiconductor device 400. In FIG. 16, the same reference numerals are used to denote the same elements as in FIGS. 2A to 2D, and detailed descriptions thereof are omitted.

Referring to FIG. 16, the memory cell array MCA of the semiconductor device 400 may include a stack structure and a plurality of channel structures 480 passing through the stack structure. The stack structure may include a gate stack GS4 including a plurality of gate lines 430 and a plurality of insulating patterns 490.

Details of the plurality of gate lines 430 may be the same as or substantially similar to details of the plurality of gate lines 130 described with reference to FIGS. 2A to 2D. The plurality of insulating patterns 490 may be respectively between the plurality of gate lines 430. Each of the plurality of insulating patterns 490 may include an air gap AG4 and a sealing insulating film 492 surrounding the air gap AG4. The air gap AG4 may include atmospheric gas or other gases that may be during a manufacturing process. The sealing insulating film 492 may include a silicon oxide film, without being limited thereto. The plurality of insulating patterns 490 may protrude more toward the center of the channel structure 480 than the plurality of gate lines 430.

Each of the plurality of channel structures 480 may include a composite domain dielectric film 482, a channel film 484, and an insulating plug 486, which are sequentially stacked from the plurality of gate lines 430 toward the center of the channel structure 480.

The composite domain dielectric film 482 may have the same or substantially similar configuration as the composite domain dielectric film 182 described with reference to FIGS. 2A to 2D. However, the composite domain dielectric film 482 may conformally cover sidewalls of each of the plurality of insulating patterns 490 and the plurality of gate lines 430, which face the channel film 484. Accordingly, the composite domain dielectric film 482 may include portions respectively protruding toward the plurality of gate lines 430 in a lateral direction and portions protruding toward the insulating plug 486 in the lateral direction. Details of the composite domain dielectric film 482 may be the same as or substantially similar to those of the composite domain dielectric film 182 described with reference to FIGS. 2A to 2D.

The channel film 484 may include a first channel film 484A and a second channel film 484B, which extend parallel to each other in the vertical direction (Z direction). The first channel film 484A and the second channel film 484B, which are in the channel film 484, may be in contact with each other. The first channel film 484A may include a surface in contact with the composite domain dielectric film 482 and a surface in contact with the second channel film 484B. The second channel film 484B may be apart from the composite domain dielectric film 482 with the first channel film 484A therebetween in the lateral direction. Details of the first channel film 484A and the second channel film 484B may be the same as those of the first channel film 284A and the second channel film 284B, which have been described with reference to FIG. 14.

In example embodiments, a selected one of the first channel film 484A and the second channel film 484B may include a p-type an oxide semiconductor, and the other selected one of the first channel film 484A and the second channel film 484B may include an n-type an oxide semiconductor. Details of the p-type an oxide semiconductor and the n-type an oxide semiconductor are the same as those described with reference to FIGS. 2A to 2D.

Each of the composite domain dielectric film 482 and the channel film 484 may include a portion between the middle insulating film 187 and the conductive pad 190. The insulating plug 486 may fill a space defined by the channel film 484 between a common source line CSL and the conductive pad 190. In some example embodiments, the insulating plug 486 may include a silicon oxide film, without being limited thereto.

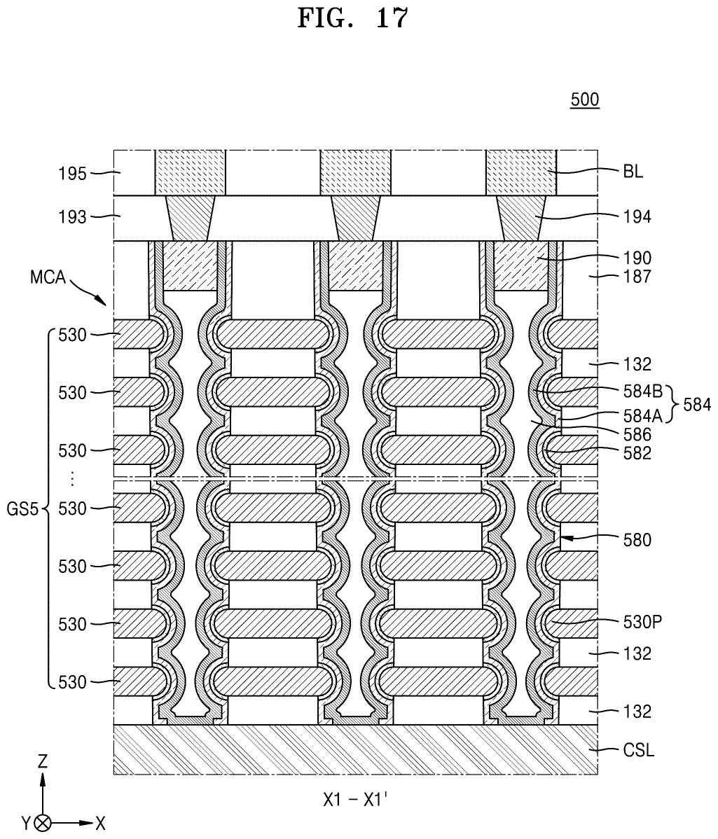

FIG. 17 is a cross-sectional view of a semiconductor device 500 according to an example embodiment. FIG. 17 illustrates a partial cross-sectional configuration of a region corresponding to a cross-section taken along line X1-X1′ of FIG. 2A in a memory cell array MCA of the semiconductor device 500. In FIG. 17, the same reference numerals are used to denote the same elements as in FIGS. 2A to 2D, and detailed descriptions thereof are omitted.

Referring to FIG. 17, the memory cell array MCA of the semiconductor device 700 may include a stack structure and a plurality of channel structures 580 passing through the stack structure. The stack structure may include a gate stack GS7 including a plurality of gate lines 730 and a plurality of insulating patterns 132. The plurality of insulating patterns 132 may be respectively one-by-one between the plurality of gate lines 530.

Details of the plurality of gate lines 530 may be the same as or substantially similar to details of the plurality of gate lines 130 described with reference to FIGS. 2A to 2D. However, each of the plurality of gate lines 530 may include a protrusion 530P, which protrudes more toward the center of the channel structure 580 than the plurality of insulating patterns 132. The protrusion 530P of each of the plurality of gate lines 530 may have a curved surface, which is convex toward the center of the channel structure 580.

Each of the plurality of channel structures 580 may include a plurality of composite domain dielectric films 582, a channel film 584, and an insulating plug 586, which are sequentially stacked from the plurality of gate lines 530 toward the center of the channel structure 580.

The plurality of composite domain dielectric films 582 included in one channel structure 580 may be apart from each other in a vertical direction (Z direction). Each of the plurality of composite domain dielectric films 582 may conformally cover the protrusion 530P of the gate line 530. Each of the plurality of composite domain dielectric films 582 may have a curved surface facing the protrusion 530P of the gate line 530. Accordingly, one gate line 530 and one composite domain dielectric film 582 may be in contact with each other along a curved surface of the protrusion 530P. Therefore, as compared to a case in which there is a planar contact surface between the gate line 530 and the composite domain dielectric film 582, a contact area between the gate line 530 and the composite domain dielectric film 582 may be increased. Thus, after the semiconductor device 500 including the composite domain dielectric film 582 including a ferroelectric material is programmed, charge tunneling in the composite domain dielectric film 582 may be reduced, and retention characteristics of the composite domain dielectric film 582 may improve. Details of the plurality of composite domain dielectric films 582 may be the same as or substantially similar to those of the composite domain dielectric film 182 described with reference to FIGS. 2A to 2D.

The channel film 584 may include a first channel film 584A and a second channel film 584B, which extend parallel to each other in the vertical direction (Z direction). The first channel film 584A and the second channel film 584B, which are in the channel film 584, may be in contact with each other. The first channel film 584A may have surfaces in contact with the plurality of composite domain dielectric films 582 and a surface in contact with the second channel film 584B. The second channel film 584B may be apart from the composite domain dielectric film 582 with the first channel film 584A therebetween in a lateral direction. Details of the first channel film 584A and the second channel film 584B may be the same as those of the first channel film 284A and the second channel film 284B, which have been described with reference to FIG. 14.

In some example embodiments, a selected one of the first channel film 584A and the second channel film 584B may include a p-type an oxide semiconductor, and the other selected one of the first channel film 584A and the second channel film 584B may include an n-type an oxide semiconductor. Details of the p-type an oxide semiconductor and the n-type an oxide semiconductor are the same as those described with reference to FIGS. 2A to 2D.

The channel film 584 may have a curved surface facing the protrusion 530P of the gate line 530. The channel film 584 may include a portion between a middle insulating film 187 and a conductive pad 190. the insulating plug 586 may fill a space defined by the channel film 584 between a common source line CSL and the conductive pad 190. In some example embodiments, the insulating plug 586 may include a silicon oxide film, without being limited thereto.

Next, methods of manufacturing semiconductor devices, according to some example embodiments, are described in detail.

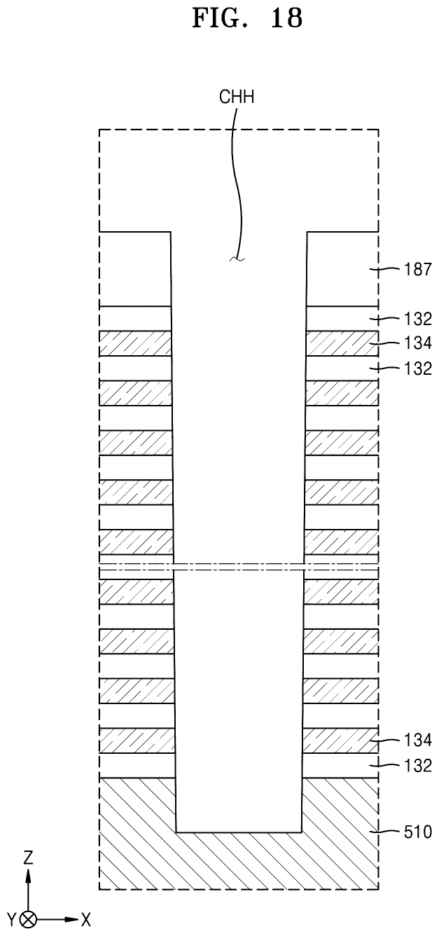

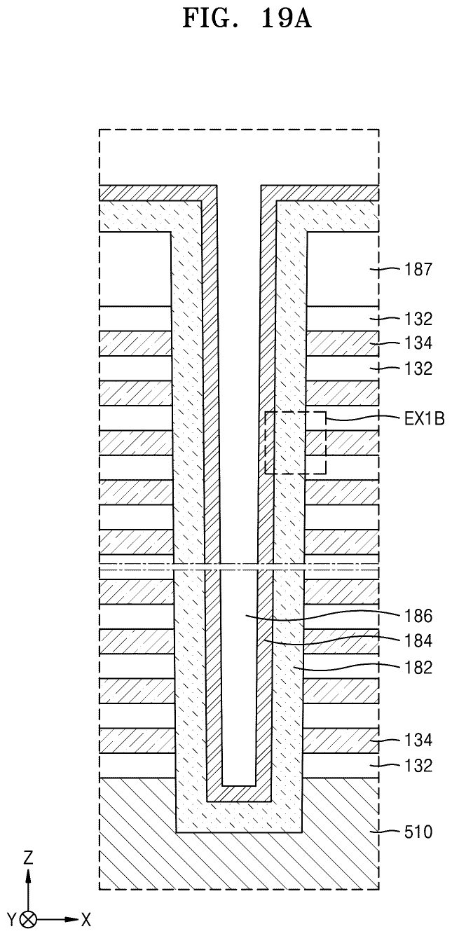

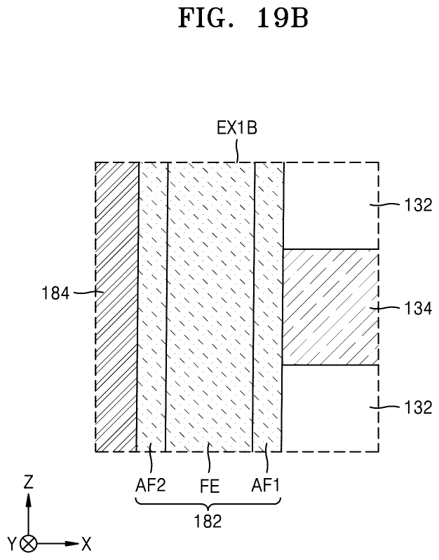

FIGS. 18 to 26 are cross-sectional views of a method of manufacturing a semiconductor device, according to an example embodiment. FIGS. 18, 19A, 20, 21A, 22A, and 23 to 26 are each an enlarged cross-sectional view of a region corresponding to region “EX1A” of FIG. 2B, according to a process sequence. FIGS. 19B, 21B, and 22B are respectively enlarged cross-sectional views of regions “EX1B” of FIGS. 19A, 21A, and 22A. An example of a method of manufacturing the semiconductor device 100A shown in FIGS. 2A to 2D is described with reference to FIGS. 18 to 26. In FIGS. 18 to 26, the same reference numerals are used to denote the same elements as in FIGS. 2A to 2D, and detailed descriptions thereof are omitted.

Referring to FIG. 18, a plurality of insulating films and a plurality of sacrificial insulating films may be alternately one-by-one on a sacrificial substrate 510. Thereafter, a middle insulating film 187 may be formed on an uppermost one of the plurality of insulating films. Afterwards, a vertical hole CHH passing through the plurality of insulating films, the plurality of sacrificial insulating films, and the middle insulating film 187 and extending in a vertical direction (Z direction) may be formed. Thus, a plurality of insulating patterns 132 and a plurality of sacrificial patterns 134, which define the vertical hole CHH, may be formed. The vertical hole CHH may be formed to pass through a portion of the sacrificial substrate 510.

The sacrificial substrate 510 may include silicon. The plurality of insulating patterns 132 may include a silicon oxide film, and the plurality of sacrificial patterns 134 may include a silicon nitride film. Each of the plurality of sacrificial patterns 134 may serve to ensure a space for forming a gate stack (refer to GS in FIGS. 2B and 2C) in a subsequent process.

Referring to FIGS. 19A and 19B, in the resultant structure of FIG. 18, a composite domain dielectric film 182, a channel film 184, and an insulating plug 186 may be sequentially formed on exposed surfaces inside and outside the vertical hole CHH.

The composite domain dielectric film 182 may include a first sub-domain AF1, a main domain FE, and a second sub-domain AF2, which are sequentially stacked on a sidewall of each of the plurality of insulating patterns 132 and the plurality of sacrificial patterns 134. Each of the first sub-domain AF1, the main domain FE, and the second sub-domain AF2 may be formed to extend long in the vertical direction (Z direction) inside the vertical hole CHH. The composite domain dielectric film 182 and the channel film 184 may be formed by using an atomic layer deposition (ALD) process. The insulating plug 186 may be formed by using an ALD process or a chemical vapor deposition (CVD) process.

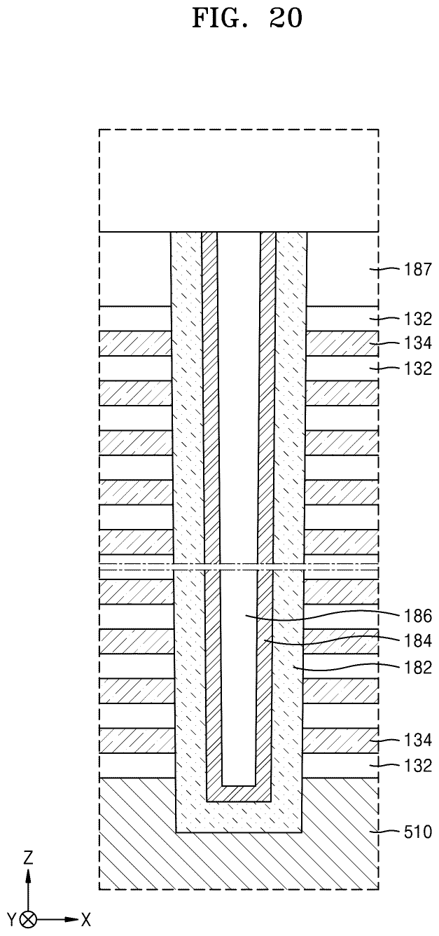

Referring to FIG. 20, the resultant structure of FIGS. 19A and 19B may be planarized to expose a top surface of the middle insulating film 187. The planarization process may be performed by using a chemical mechanical polishing (CMP) process.

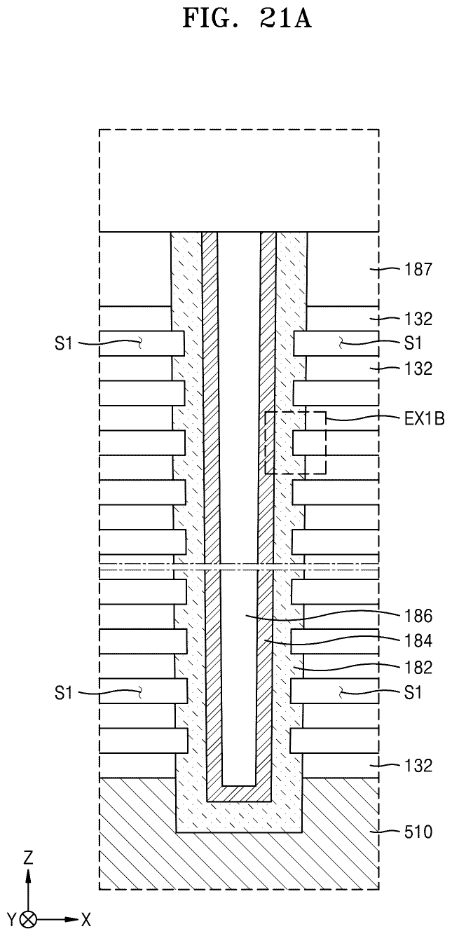

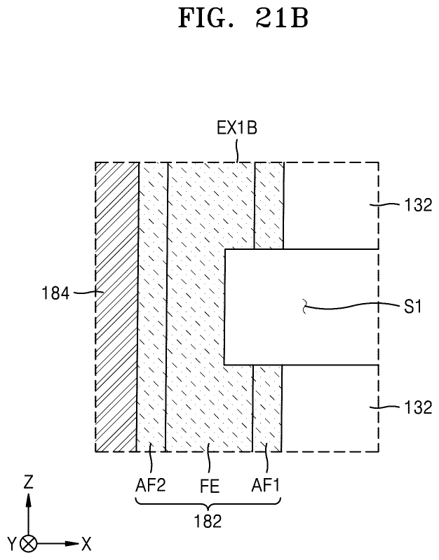

Referring to FIGS. 21A and 21B, the plurality of sacrificial patterns 134 may be removed from the resultant structure of FIG. 20 to form a plurality of gate spaces S1. To form the plurality of gate spaces S1, the plurality of word line cut regions WLC described with reference to FIG. 2A may be formed beforehand, and the plurality of sacrificial patterns 134 may be removed through the plurality of word line cut regions WLC.

Thereafter, partial regions of the first sub-domain AF1, which are exposed through the plurality of gate spaces S1, may be removed to expose the main domain FE. Subsequently, a portion of the main domain FE may be removed. As a result, the first sub-domain AF1 may be divided into a plurality of first sub-domains AF1, and a lateral width of the main domain FE may be variable in the vertical direction (Z direction).

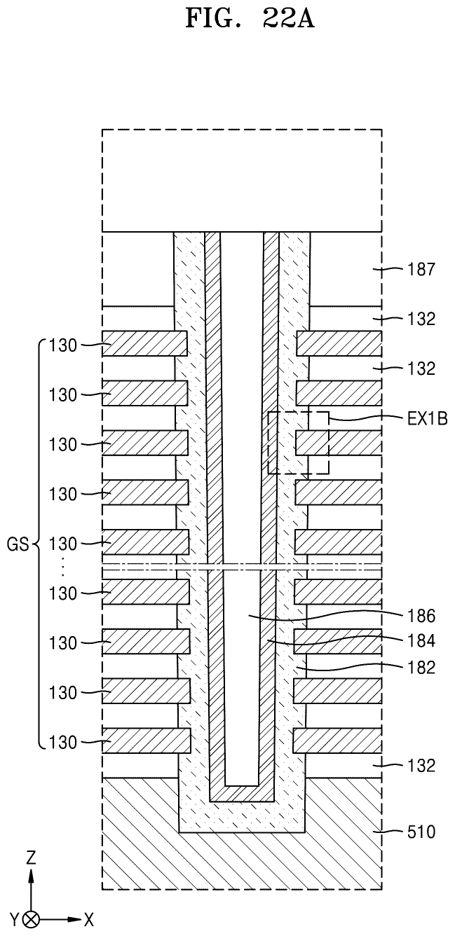

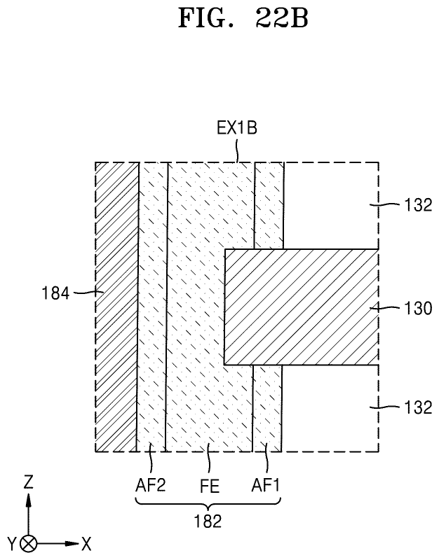

Referring to FIGS. 22A and 22B, in the resultant structure of FIGS. 21A and 21B, the plurality of gate spaces S1 may be filled by a plurality of gate lines 130. Thereafter, as shown in FIG. 2A, the inside of each of the plurality of word line cut regions WLC may be filled by a word line cut structure 192.

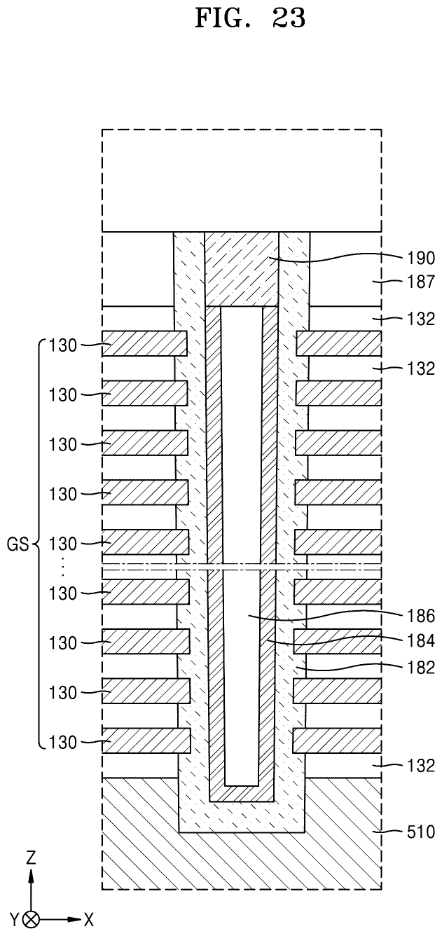

Referring to FIG. 23, a portion of each of the channel film 184 and the insulating plug 186 may be removed from the resultant structure of FIGS. 22A and 22B, and thus, a space may be provided in an upper portion of the vertical hole CHH. A conductive pad 190 may be formed to fill the space.

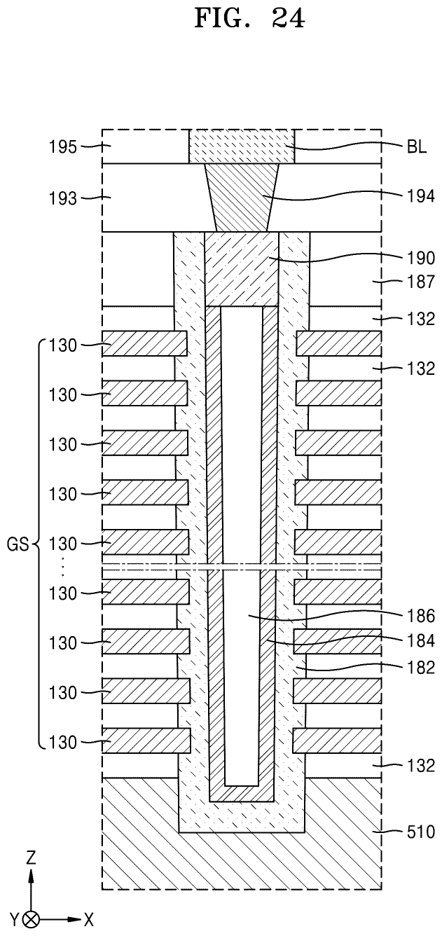

Referring to FIG. 24, a first upper insulating film 193, a bit line contact pad 194, a second upper insulating film 195, and a bit line may be formed. The first upper insulating film 193 may cover the conductive pad 190, the composite domain dielectric film 182, and the middle insulating film 187. The bit line contact pad 194 may pass through the first upper insulating film 193 and be connected to the conductive pad 190. The bit line BL may pass through the second upper insulating film 195 and be connected to the bit line contact pad 194.

In other example embodiments, to manufacture the semiconductor device 100B shown in FIG. 3, a wiring structure MS, a plurality of first bonding metal pads 178A, and an interlayer insulating film 150 filling spaces between the wiring structure MS and the plurality of first bonding metal pads 178A may be formed on the bit line BL. The wiring structure MS may include a plurality of first upper wiring layers 172, a plurality of second upper wiring layers 174, and a plurality of third upper wiring layers 176. In addition, the peripheral circuit structure PCS shown in FIG. 3 may be formed, the plurality of first bonding metal pads 178A included in a cell array structure CAS may be bonded to the plurality of second bonding metal pads 178B included in the peripheral circuit structure PCS to form a plurality of bonding structures BS. Thus, the cell array structure CAS may be bonded onto the peripheral circuit structure PCS.

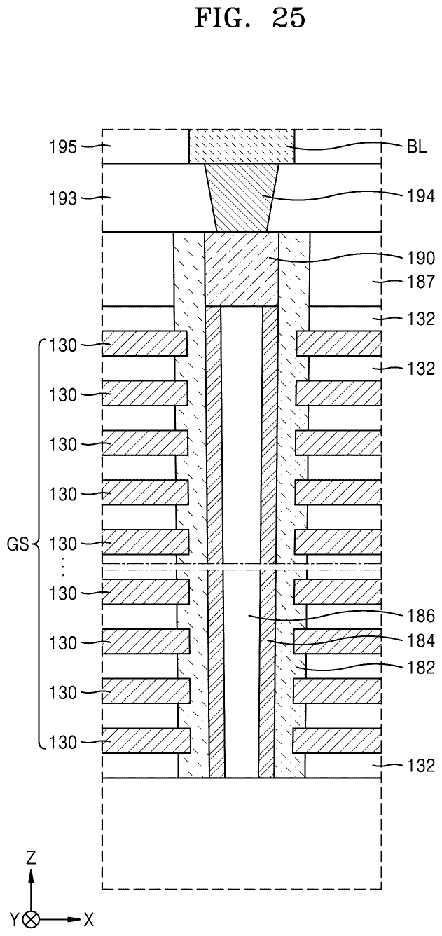

Referring to FIG. 25, the resultant structure obtained by removing the sacrificial substrate 510 from the resultant structure of FIG. 24 may be planarized to expose the insulating pattern 132, the composite domain dielectric film 182, the channel film 184, and the insulating plug 186.

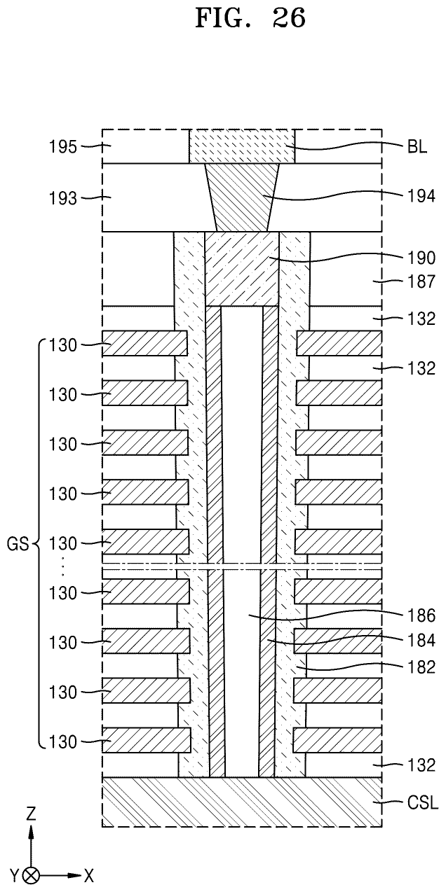

Referring to FIG. 26, in the resultant structure of FIG. 25, a common source line CSL may be formed to cover exposed surfaces of the insulating pattern 132, the composite domain dielectric film 182, the channel film 184, and the insulating plug 186.

In other example embodiments, to manufacture the semiconductor device 100B shown in FIG. 3, an insulating film 106 may be formed to cover the common source line CSL as shown in FIG. 3.

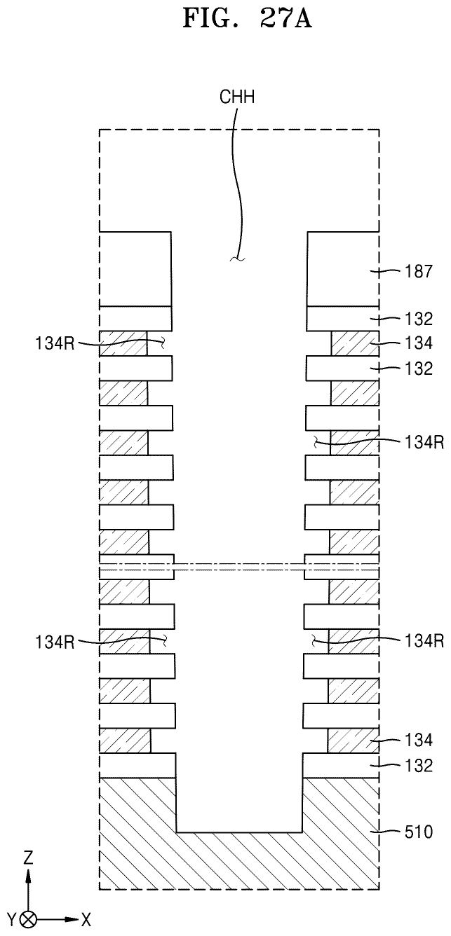

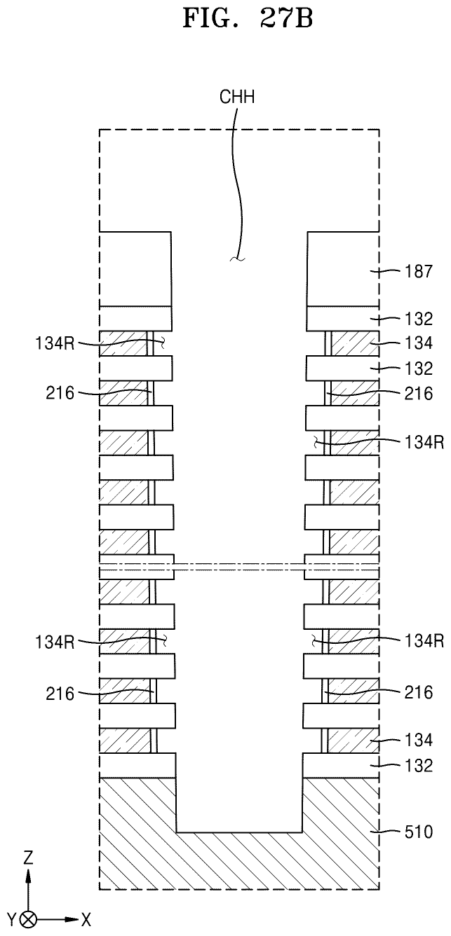

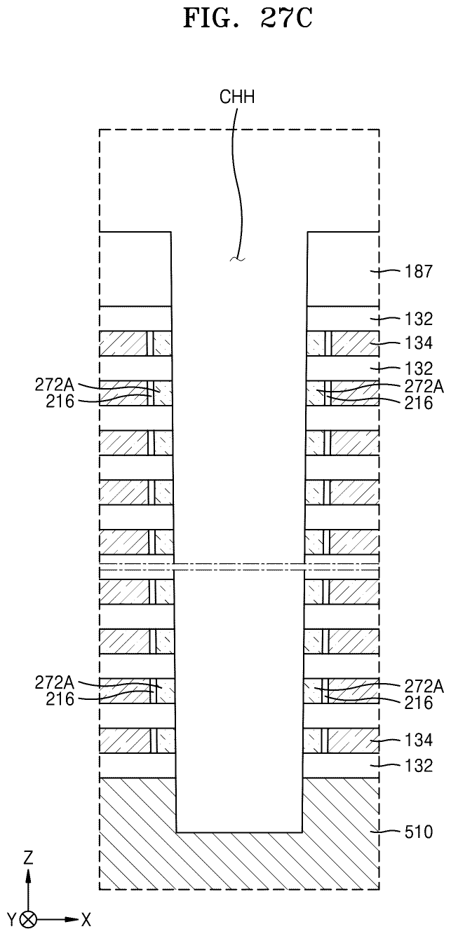

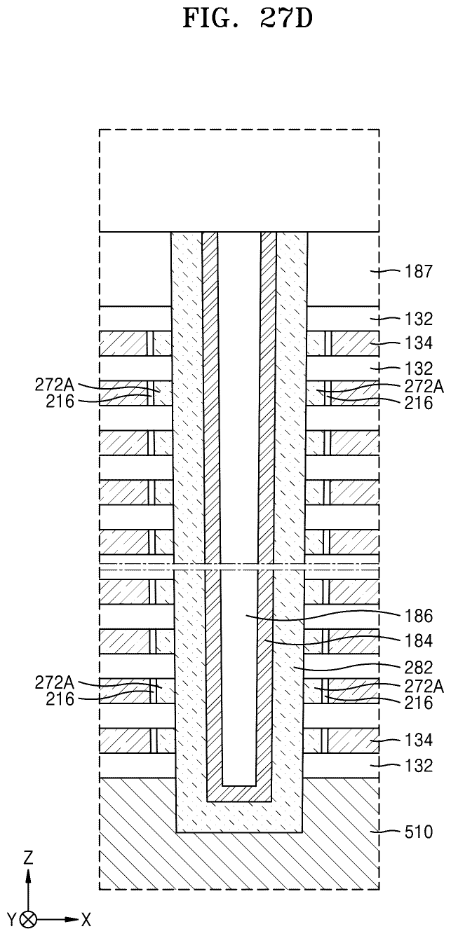

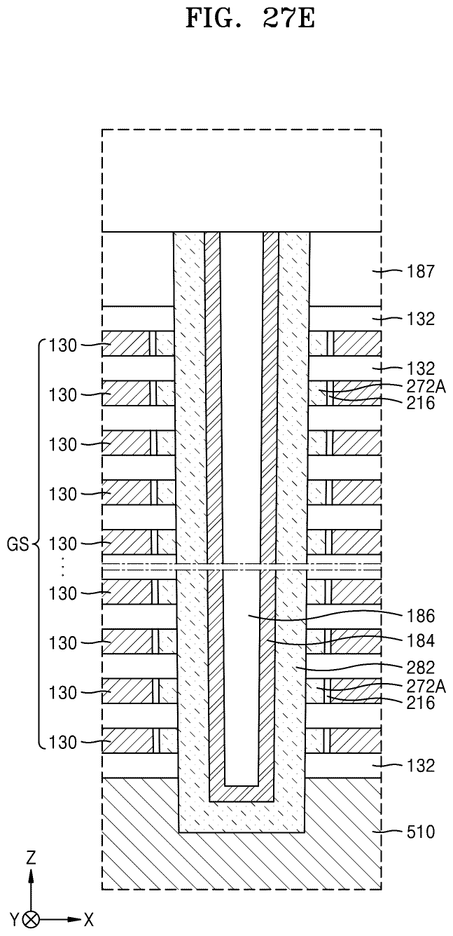

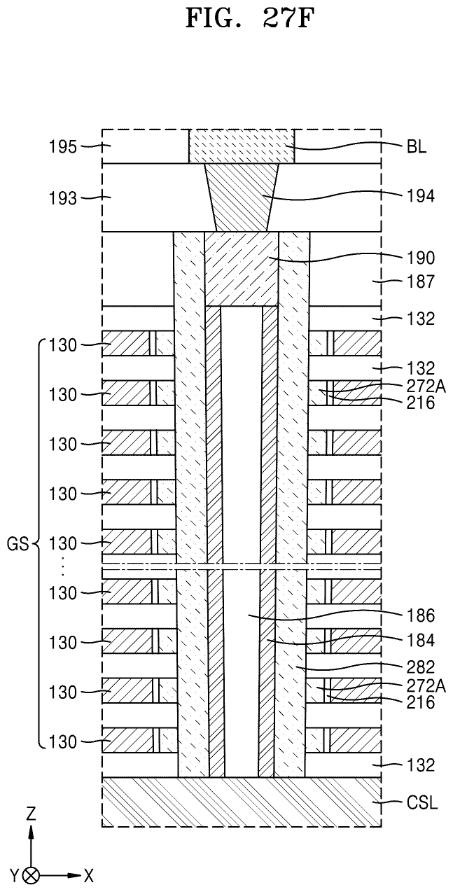

FIGS. 27A to 27F are cross-sectional views of a method of manufacturing a semiconductor device, according to an example embodiment. An example of a method of manufacturing the semiconductor device 200A shown in FIGS. 10A to 10C is described with reference to FIGS. 27A to 27F. FIGS. 27A to 27F each illustrate an enlarged cross-sectional configuration of a region corresponding to region “EX2A” of FIG. 10A, according to a process sequence. In FIGS. 27A to 27F, the same reference numerals are used to denote the same elements as in FIGS. 2A to 10C, and detailed descriptions thereof are omitted.

Referring to FIG. 27A, by using a method similar to that described with reference to FIG. 18, a plurality of insulating patterns 132, a plurality of sacrificial patterns 134, and a middle insulating film 187, which define a vertical hole CHH, may be formed on a sacrificial substrate 510. Thereafter, respective portions of the plurality of sacrificial patterns 134 may be selectively etched from sidewalls of the plurality of sacrificial patterns 134, which are exposed through the vertical hole CHH. Thus, a plurality of recess regions 134R, which are connected to the vertical hole CHH, may be respectively formed between the plurality of sacrificial patterns 132. To selectively etch the respective portions of the plurality of sacrificial patterns 134, from among the plurality of insulating patterns 132 and the plurality of sacrificial patterns 134, the plurality of sacrificial patterns 134 may be selectively wet etched.

Referring to FIG. 27B, in the resultant structure of FIG. 18, a plurality of dielectric films 216 may be formed on surfaces of the plurality of sacrificial patterns 134, which are exposed through the plurality of recess regions 134R. In some example embodiments, the plurality of dielectric films 216 may include a silicon oxide film, without being limited thereto.

Referring to FIG. 27C, in the resultant structure of FIG. 27B, a plurality of local composite dielectric films 272A may be formed to fill the plurality of recess regions 134R.

In some example embodiments, to form the plurality of local composite dielectric films 272A, a first domain AF1A, a second domain FE2A, and a third domain AF2A, which have the same shapes as those shown in FIG. 10C, may be formed in the plurality of recess regions 134R. In other example embodiments, instead of the plurality of local composite dielectric films 272A, a local composite dielectric film 272B including a first domain AF1B, a second domain FE2B, and a third domain AF2B as shown in FIG. 11 may be formed in the plurality of recess regions 134R.

Referring to FIG. 27D, processes similar to those described with reference to FIGS. 19A, 19B, and 20 may be performed on the resultant structure of FIG. 27C. Thus, a composite domain dielectric film 282, a channel film 184, and an insulating plug 186 may be formed to fill the vertical hole CHH.

Referring to FIG. 27E, by using a method similar to that described with reference FIGS. 21A to 22B, the plurality of sacrificial patterns 134 remaining in the resultant structure of FIG. 27D may be replaced by a plurality of gate lines 130.

Referring to FIG. 27F, processes similar to those described with reference to FIGS. 23 to 26 may be performed on the resultant structure of FIG. 27E. Thus, the semiconductor device 200A shown in FIGS. 10A to 10C may be manufactured.

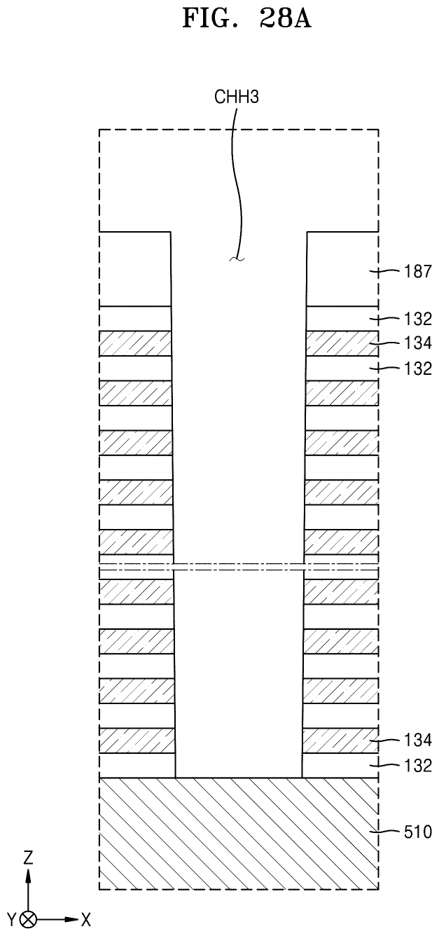

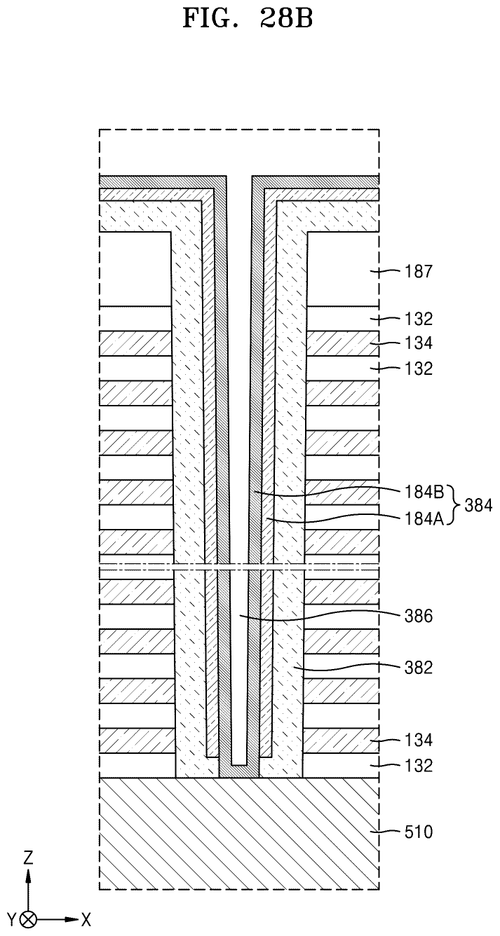

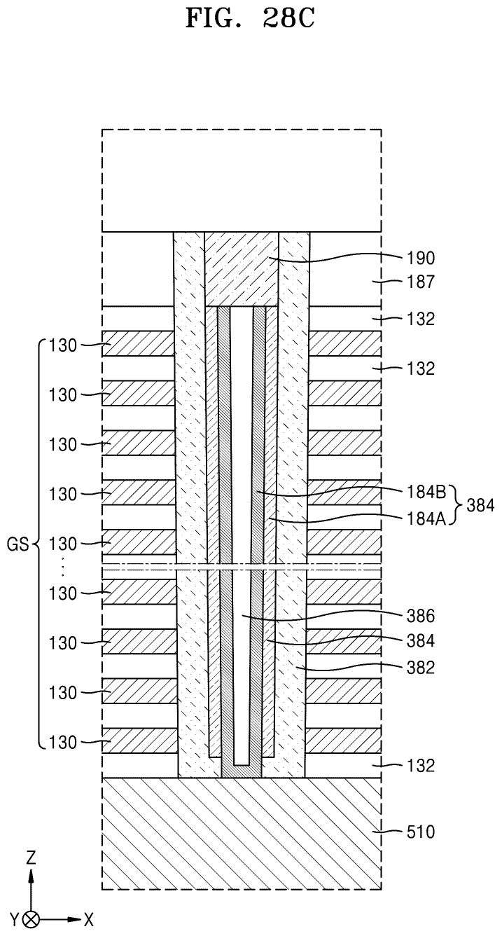

FIGS. 28A to 28C are cross-sectional views of a method of manufacturing a semiconductor device, according to an example embodiment. An example of a method of manufacturing the semiconductor device 300 shown in FIG. 15 is described with reference to FIGS. 28A to 28C. In FIGS. 28A to 28C, the same reference numerals are used to denote the same elements as in FIGS. 2A to 15, and detailed descriptions thereof are omitted.

Referring to FIG. 28A, by using a method similar to that described with reference to FIG. 18, a plurality of insulating patterns 132, a plurality of sacrificial patterns 134, and a middle insulating film 187, which define a vertical hole CHH3, may be formed on a sacrificial substrate 510. A top surface of the sacrificial substrate 510 may be exposed through the vertical hole CHH3.

Referring to FIG. 28B, in the resultant structure of FIG. 28A, a composite domain dielectric film 382 and a first channel film 184A may be formed to conformally cover exposed surfaces inside the vertical hole CHH3. Thereafter, respective portions of the composite domain dielectric film 382 and the first channel film 184A may be removed, and thus, the top surface of the sacrificial substrate 510 may be exposed at the center of the bottom of the vertical hole (refer to CHH3 in FIG. 28A). Afterwards, a second channel film 184B may be formed to conformally cover the composite domain dielectric film 382, the first channel film 184A, and the sacrificial substrate 510, which are exposed inside the vertical hole CHH3. The first channel film 184A and the second channel film 184B may constitute a channel film 384. Thereafter, the inside of the vertical hole CHH3 may be filled by an insulating plug 386 on the second channel film 184B.

Referring to FIG. 28C, processes similar to those described with reference to FIGS. 20 to 26 may be performed on the resultant structure of FIG. 28B, and thus, the semiconductor device 300 shown in FIG. 15 may be manufactured.

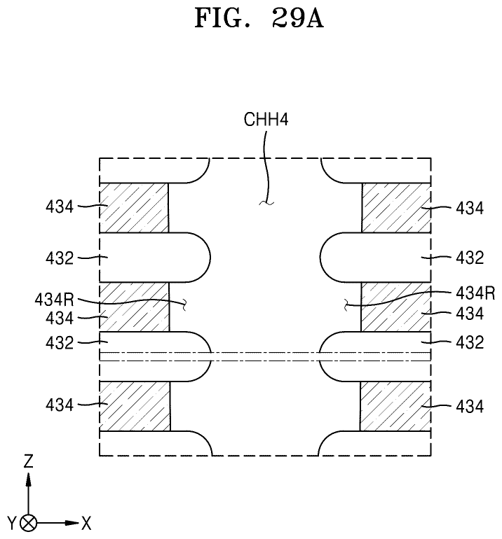

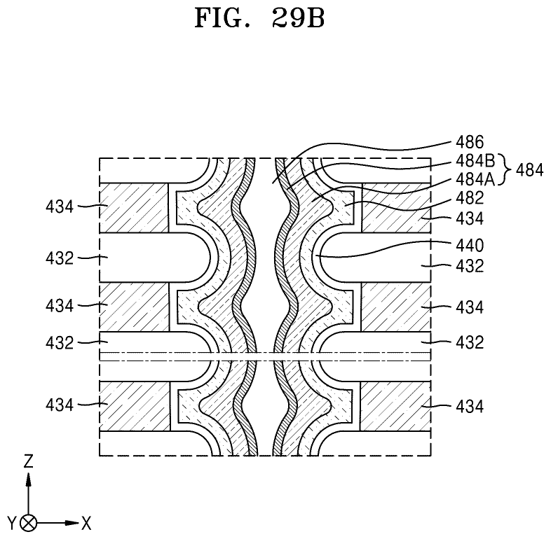

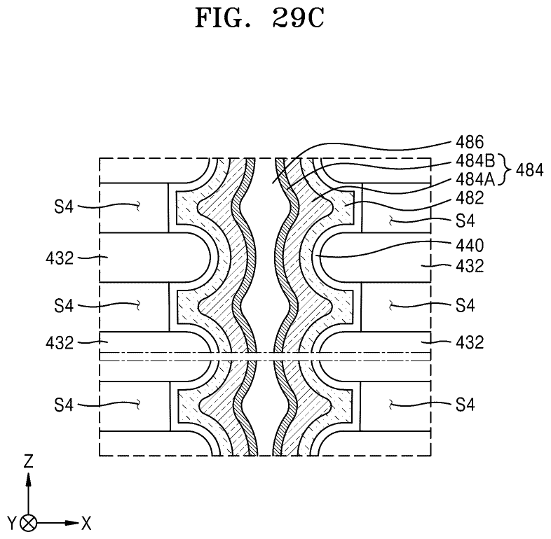

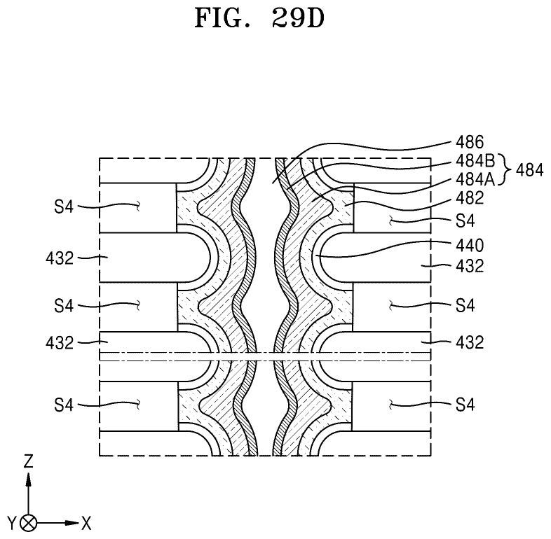

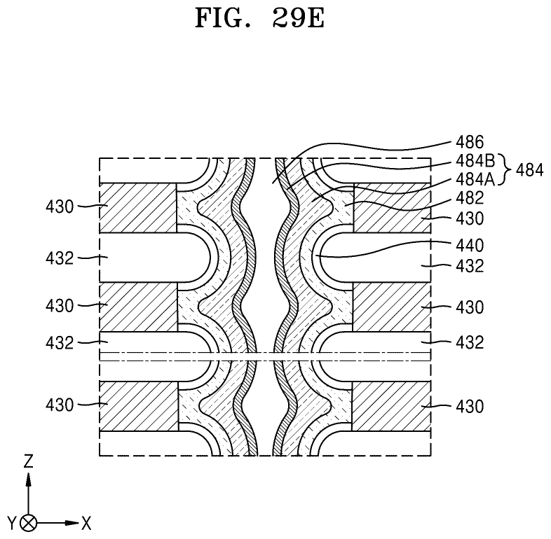

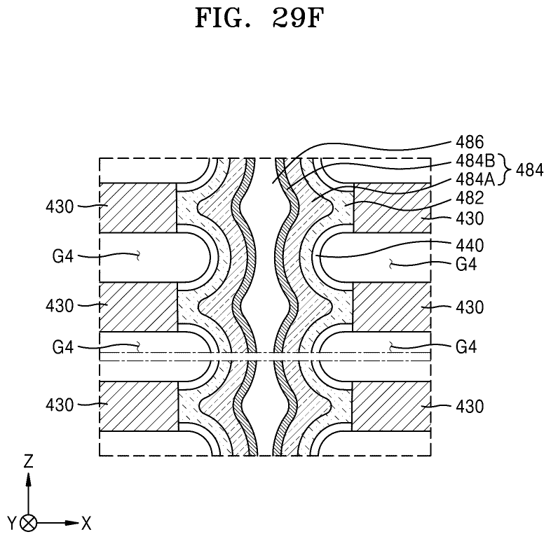

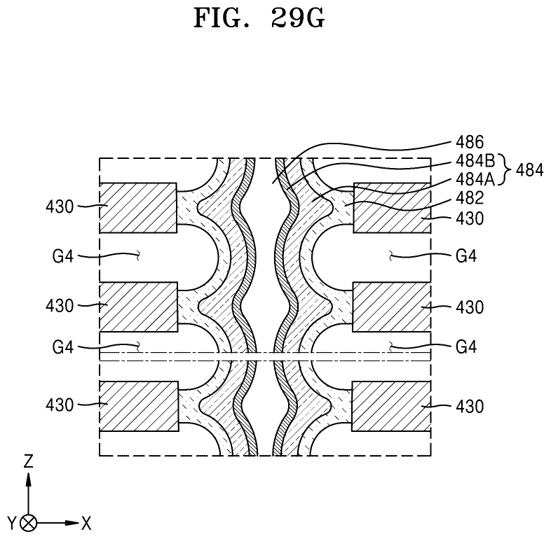

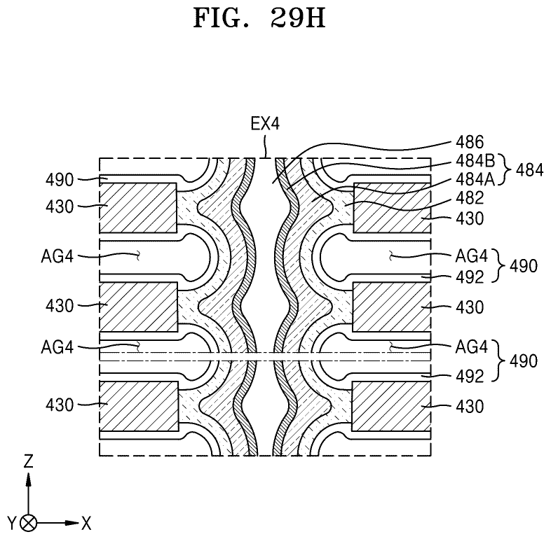

FIGS. 29A to 29H are cross-sectional views of a method of manufacturing a semiconductor device, according to an example embodiment. An example of a method of manufacturing the semiconductor device 400 shown in FIG. 16 is described with reference to FIGS. 29A to 29H. FIGS. 29A to 29H each illustrate an enlarged cross-sectional configuration of a region corresponding to region “EX4” of FIG. 16, according to a process sequence. In FIGS. 29A to 29H, the same reference numerals are used to denote the same elements as in FIGS. 2A to 16, and detailed descriptions thereof are omitted.

Referring to FIG. 29A, by using a method similar to that described with reference to FIG. 18, a plurality of insulating patterns 432, a plurality of sacrificial patterns 434, and a middle insulating film (refer to 187 in FIG. 16), which define a vertical hole CHH4, may be formed on a sacrificial substrate 510. Afterwards, by using a method similar to that described with reference to FIG. 27A, respective portions of the plurality of sacrificial patterns 434 may be selectively etched from sidewalls of the plurality of sacrificial patterns 434, which are exposed through the vertical hole CHH4. Thus, a plurality of recess regions 434R, which are connected to the vertical hole CHH4, may be formed between the plurality of sacrificial patterns 432, respectively. During the selective etching of the respective portions of the plurality of sacrificial patterns 434, portions of protrusions of the plurality of insulating patterns 432 exposed inside the vertical hole CHH4 may be consumed due to an etching atmosphere, and thus, the protrusions of the plurality of insulating patterns 432 may have round shapes.

Referring to FIG. 29B, in the resultant structure of FIG. 29A, a sacrificial film 440 maybe formed to conformally cover exposed surfaces inside the vertical hole CHH4. By using a method similar to that described with reference to FIGS. 19A, 19B, and 20, a composite domain dielectric film 482, a channel film 484, and an insulating plug 486 may be sequentially formed on the sacrificial film 440. The channel film 484 may be formed to have a double structure including a first channel film 484A and a second channel film 484B.

Referring to FIG. 29C, the plurality of sacrificial patterns 434 may be removed from the resultant structure of FIG. 29B by using a method similar to that described with reference to FIGS. 21A and 21B, and thus, a plurality of gate spaces S4 may be formed. The sacrificial film 440 may be exposed through the plurality of gate spaces S4.

Referring to FIG. 29D, the sacrificial film 440 exposed through the plurality of gate spaces S4 may be removed from the resultant structure of FIG. 29C, and thus, the composite domain dielectric film 482 may be exposed through the plurality of gate spaces S4.

Referring to FIG. 29E, by using a method similar to that described with reference to FIGS. 22A and 22B, the plurality of gate spaces S4 may be filled with a plurality of gate lines 430 in the resultant structure of FIG. 29D.

Referring to FIG. 29F, the plurality of insulating patterns 432 may be removed from the resultant structure of FIG. 29E, and thus, a plurality of insulating spaces G4 may be respectively provided one-by-one between the plurality of gate lines 430. The sacrificial film 440 may be exposed through the plurality of insulating spaces G4.

Referring to FIG. 29G, the sacrificial film 440 exposed through the plurality of insulating spaces G4 may be removed from the resultant structure of FIG. 29F. Thus, the composite domain dielectric film 482 may be exposed through the plurality of insulating spaces G4.

Referring to FIG. 29H, in the resultant structure of FIG. 29G, a plurality of insulating patterns 490 may be formed in the plurality of insulating spaces G4. To form the plurality of insulating patterns 490, a sealing insulating film 492 defining the air gap AG4 may be formed in each of the plurality of insulating spaces G4. In each of the plurality of insulating spaces G4, a thickness of the sealing insulating film 492 may not be constant according to positions. Subsequently, processes similar to those described with reference to FIGS. 23 to 26 may be performed, and thus, the semiconductor device 400 shown in FIG. 16 may be manufactured.

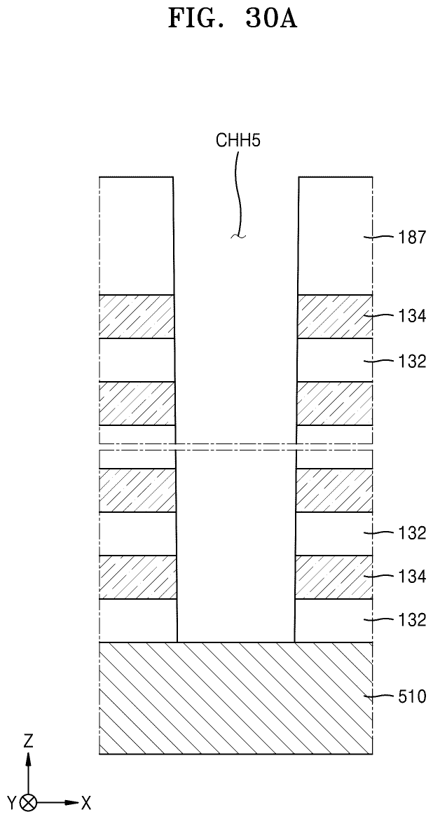

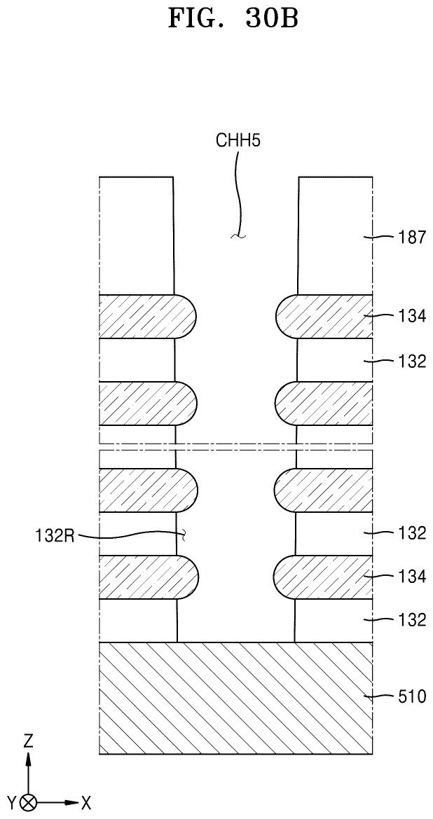

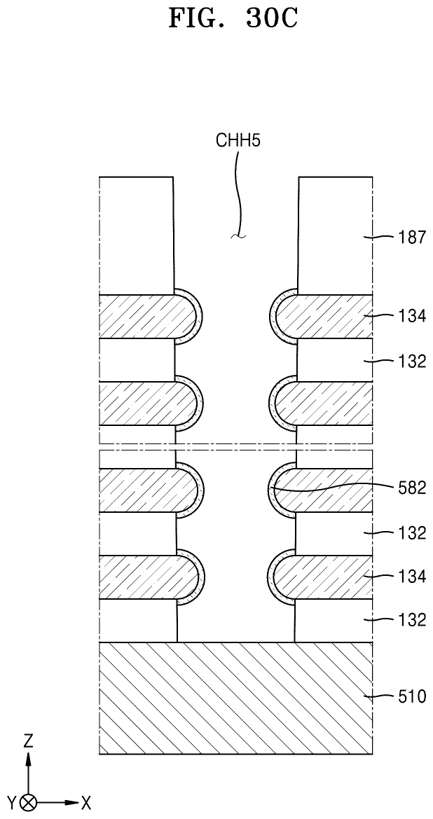

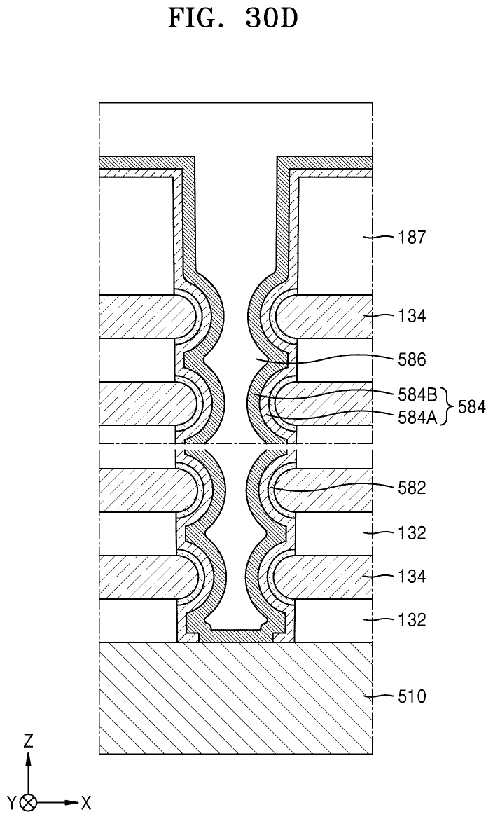

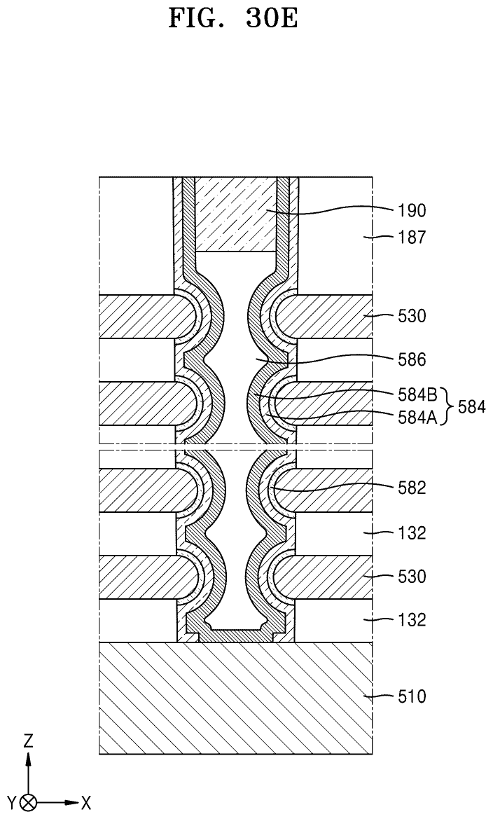

FIGS. 30A to 30E are cross-sectional views of a method of manufacturing a semiconductor device, according to an example embodiment. An example of a method of manufacturing the semiconductor device 500 shown in FIG. 17 is described with reference to FIGS. 30A to 30E. In FIGS. 30A to 30E, the same reference numerals are used to denote the same elements as in FIGS. 2A to 17, and detailed descriptions thereof are omitted.

Referring to FIG. 30A, by using a method similar to that described with reference to FIG. 18, a plurality of insulating patterns 132, a plurality of sacrificial patterns 134, and a middle insulating film 187, which define a vertical hole CHH5, may be formed on a sacrificial substrate 510.

Referring to FIG. 30B, in the resultant structure of FIG. 30A, respective portions of the plurality of insulating patterns 132 may be selectively etched from sidewalls of the plurality of insulating patterns 132, which are exposed through the vertical hole CHH5. Thus, a plurality of recess regions 132R, which are connected to the vertical hole CHH5, may be respectively formed between the plurality of sacrificial patterns 134. During the selective etching of the respective portions of the plurality of insulating patterns 132, portions of protrusions of the plurality of insulating patterns 132 exposed inside the vertical hole CHH5 may be consumed due to an etching atmosphere, and thus, the protrusions of the plurality of insulating patterns 132 may have round shapes.

Referring to FIG. 30C, in the resultant structure of FIG. 30B, a plurality of composite domain dielectric films 582 may be formed to cover surfaces of the plurality of sacrificial patterns 134, which are exposed inside the vertical hole CHH5.

In some example embodiments, to selectively form the composite domain dielectric film 582 on the surface of each of the plurality of sacrificial patterns 134, which is exposed inside the vertical hole CHH5, a selective deposition process may be performed in which a constituent material of the composite domain dielectric film 582 is not deposited on the plurality of insulating patterns 132, which are exposed inside the vertical hole CHH5, and selectively deposited only on the plurality of sacrificial patterns 134. The plurality of composite domain dielectric films 582 may be formed by using a metal organic atomic layer deposition (MOALD) process.

In some example embodiments, to form the selective deposition process, before the plurality of composite domain dielectric films 582 are formed, a deposition inhibition film (not shown) may be selectively formed only on the plurality of insulating patterns 132 exposed inside the vertical hole CHH5. After the plurality of composite domain dielectric films 582 are formed, the deposition inhibition film may be removed. In other example embodiments, the process of forming the deposition inhibition film may be omitted. However, the selective deposition process is not limited to the processes described above and may be variously changed and modified.

Referring to FIG. 30D, in the resultant structure of FIG. 30C, a channel film 584 may be formed to conformally cover exposed surfaces inside the vertical hole CHH5. A remaining space of the vertical hole CHH5, which is defined by the channel film 584, may be filled by an insulating plug 586. The channel film 584 may be formed to have a double structure including a first channel film 584A and a second channel film 584B.

Referring to FIG. 30E, processes similar to those described with reference to FIGS. 22A to 26 may be performed on the resultant structure of FIG. 30D, and thus, the semiconductor device 500 shown in FIG. 17 may be manufactured.

Although some methods of manufacturing the semiconductor devices 100A, 100B, 200, 300, 400, and 500 shown in FIGS. 2A to 2D, 3, 10A to 10C, and 15 to 17 have been described with reference to FIGS. 18 to 30E, it will be understood that semiconductor devices having variously changed structures may be manufactured by applying various modifications and changes to the processes described with reference to FIGS. 18 to 30E within the scope of the inventive concepts.

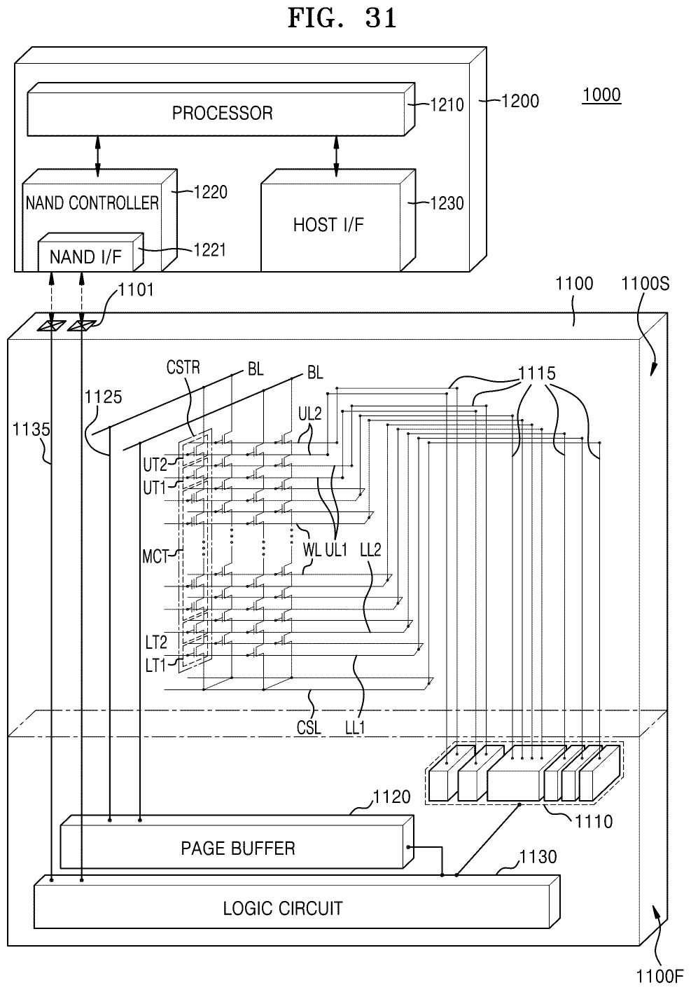

FIG. 31 is a diagram of an electronic system including a semiconductor device according to an example embodiment.

Referring to FIG. 31, the electronic system 1000 according to the embodiment may include a semiconductor device 1100 and a controller 1200 electrically connected to the semiconductor device 1100. The electronic system 1000 may be a storage device including at least one semiconductor device 1100 or an electronic device including the storage device. For example, the electronic system 1000 may include a solid-state drive (SSD) device, a universal serial bus (USB), a computing system, a medical device, or a communication device, which includes the at least one semiconductor device 1100.

The semiconductor device 1100 may include a non-volatile memory. For example, the semiconductor device 1100 may include a NAND flash memory device including at least one of the structures of the semiconductor devices 100A to 100H, 200A to 200E, 300, 400, and 500, which have been described with reference to FIGS. 2A to 17. The semiconductor device 1100 may include a first structure 1100F and a second structure 1100S on the first structure 1100F. In some example embodiments, the first structure 1100F may be beside the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, a plurality of word lines WL, first and second gate upper lines UL1 and UL2, first and second gate lower lines LL1 and LL2, and a plurality of memory cell strings CSTR between the bit line BL and the common source line CSL.

In the second structure 1100S, each of the plurality of memory cell strings CSTR may include lower transistors LT1 and LT2 adjacent to the common source line CSL, upper transistors UT1 and UT2 adjacent to the bit line BL, and a plurality of memory cell transistors MCT between the lower transistors LT1 and LT2 and the upper transistors UT1 and UT2. The number of lower transistors (e.g., LT1 and LT2) and the number of upper transistors (e.g., UT1 and UT2) may be variously changed according to embodiments.

In some example embodiments, the upper transistors UT1 and UT2 may include a string selection transistor, and the lower transistors LT1 and LT2 may include a ground selection transistor. The first and second gate lower lines LL1 and LL2 may be respectively gate electrodes of the lower transistors LT1 and LT2. The word line WL may be a gate electrode of the memory cell transistor MCT, and the first and second gate upper lines UL1 and UL2 may be gate electrodes of the upper transistors UT1 and UT2.

The common source line CSL, the first and second gate lower lines LL1 and LL2, the plurality of word lines WL, and the first and second gate upper lines UL1 and UL2 may be electrically connected to the decoder circuit 1110 through a plurality of first connecting wires 1115, which extend to the second structure 1100S in the first structure 1100F. The plurality of bit lines BL may be electrically connected to the page buffer 1120 through a plurality of second connecting wirings 1125, which extend to the second structure 1100S in the first structure 1100F.

In the first structure 1100F, the decoder circuit 1110 and the page buffer 1120 may perform a control operation on at least one of the plurality of memory cell transistors MCT. The decoder circuit 1110 and the page buffer 1120 may be controlled by the logic circuit 1130.

The semiconductor device 1100 may communicate with the controller 1200 through an I/O pad 1101 that is electrically connected to the logic circuit 1130. The I/O pad 1101 may be electrically connected to the logic circuit 1130 through I/O connection wirings 1135, which extend to the second structure 1100S in the first structure 1100F.

The controller 1200 may include a processor 1210, a NAND controller 1220, and a host interface (or host I/F) 1230. In some example embodiments, the electronic system 1000 may include a plurality of semiconductor devices 1100. In this case, the controller 1200 may control the plurality of semiconductor devices 1100.

The processor 1210 may control all operations of the electronic system 1000 including the controller 1200. The processor 1210 may operate according to predetermined firmware and may access the semiconductor device 1100 by controlling the NAND controller 1220. The NAND controller 1220 may include a NAND interface (or NAND I/F) 1221 configured to process communication with the semiconductor device 1100. A control command for controlling the semiconductor device 1100, data to be written to the plurality of memory cell transistors MCT of the semiconductor device 1100, and data to be read from the plurality of memory cell transistors MCT of the semiconductor device 1100 may be transmitted through the NAND interface 1221. The host interface 1230 may provide a communication function between the electronic system 1000 and an external host. When receiving the control command from the external host through the host interface 1230, the processor 1210 may control the semiconductor device 1100 in response to the control command.

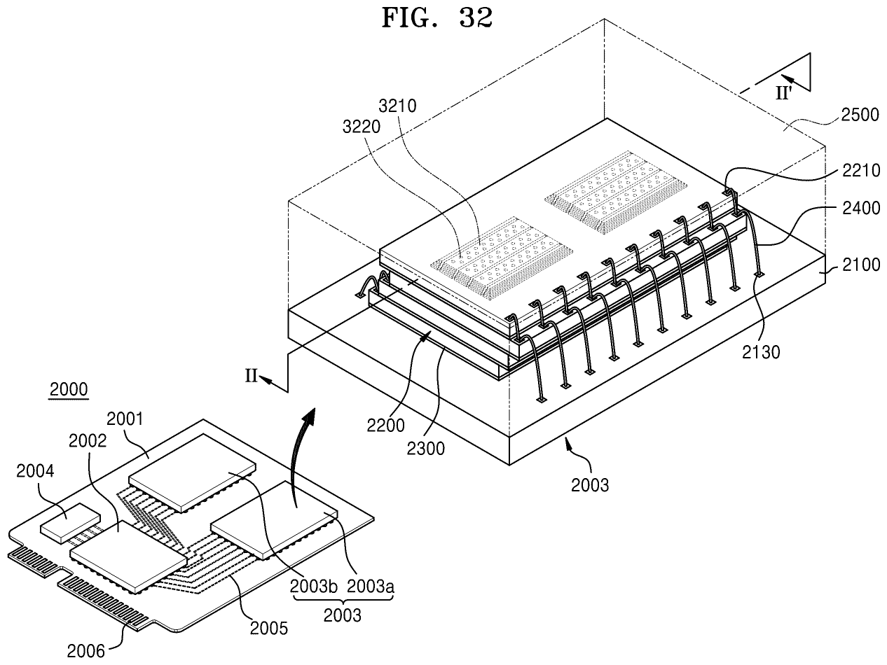

FIG. 32 is a perspective view of an electronic system 2000 including a semiconductor device, according to an example embodiment.

Referring to FIG. 32, the electronic system 2000 according to the embodiments may include a main substrate 2001, a controller 2002 mounted on the main substrate 2001, at least one semiconductor package 2003, and DRAM 2004. The at least one semiconductor package 2003 and the DRAM 2004 may be connected to the controller 2002 by a plurality of wiring patterns 2005 formed in the main substrate 2001.

The main substrate 2001 may include a connector 2006 including a plurality of pins that are combined with an external host. In the connector 2006, the number and arrangement of pins may depend on a communication interface between the electronic system 2000 and the external host. In some example embodiments, the electronic system 2000 may communicate with the external host by using any one of interfaces, such as a USB, peripheral component interconnect-express (PCI-E), serial advanced technology attachment (SATA), and M-Phy for universal flash storage (UFS). In embodiments, the electronic system 2000 may operate by power received from the external host through the connector 2006. The electronic system 2000 may further include a power management integrated circuit (PMIC) configured to divide power supplied from the external host into the controller 2002 and the at least one semiconductor package 2003.

The controller 2002 may write data to the at least one semiconductor package 2003 or read data from the at least one semiconductor package 2003 and improve an operating speed of the electronic system 2000.

The DRAM 2004 may be a buffer memory configured to reduce a speed difference between the at least one semiconductor package 2003, which is a data storage space, and the external host. The DRAM 2004 included in the electronic system 2000 may operate as a kind of cache memory and provide a space for temporarily storing data in a control operation on the at least one semiconductor package 2003. When the electronic system 2000 includes the DRAM 2004, the controller 2002 may further include a DRAM controller configured to control the DRAM 2004 in addition to a NAND controller configured to control the at least one semiconductor package 2003.

The at least one semiconductor package 2003 may include first and second semiconductor packages 2003a and 2003b, which are apart from each other. Each of the first and second semiconductor packages 2003a and 2003b may include a semiconductor package including a plurality of semiconductor chips 2200. Each of the first and second semiconductor packages 2003a and 2003b may include a package substrate 2100, the plurality of semiconductor chips 2200 on the substrate 2100, an adhesive layer 2300 on a bottom surface of each of the plurality of semiconductor chips 2200, a connection structure 2400 configured to electrically connect the plurality of semiconductor chips 2200 to the package substrate 2100, and a molding layer 2500 covering the plurality of semiconductor chips 2200 and the connection structure 2400 on the package substrate 2100.

The package substrate 2100 may be a printed circuit board (PCB) including a plurality of package upper pads 2130. Each of the plurality of semiconductor chips 2200 may include an I/O pad 2210. The I/O pad 2210 may correspond to the I/O pad 1101 of FIG. 31. Each of the plurality of semiconductor chips 2200 may include a plurality of gate stacks 3210 and a plurality of channel structures 3220. Each of the plurality of semiconductor chips 2200 may include at least one of the structures of the semiconductor devices 100A to 100H, 200A to 200E, 300, 400, and 500, which have been described with reference to FIGS. 2A to 17.

In some example embodiments, the connection structure 2400 may be a bonding wire configured to electrically connect the I/O pad 2210 to the package upper pad 2130. Accordingly, in the first and second semiconductor packages 2003a and 2003b, the plurality of semiconductor chips 2200 may be electrically connected to each other by using a bonding wire technique and electrically connected to the package upper pad 2130 of the package substrate 2100. In some example embodiments, in the first and second semiconductor packages 2003a and 2003b, the plurality of semiconductor chips 2200 may be electrically connected to each other by a connection structure including through-silicon vias (TSVs) instead of the connection structure 2400 for a bonding wire technique.

In some example embodiments, the controller 2002 and the plurality of semiconductor chips 2200 may be included in one package. In some example embodiments, the controller 2002 and the plurality of semiconductor chips 2200 may be mounted on an additional interposer substrate, which is different from the main substrate 2001, and the controller 2002 may be connected to the plurality of semiconductor chips 2200 by wirings formed on the interposer substrate.

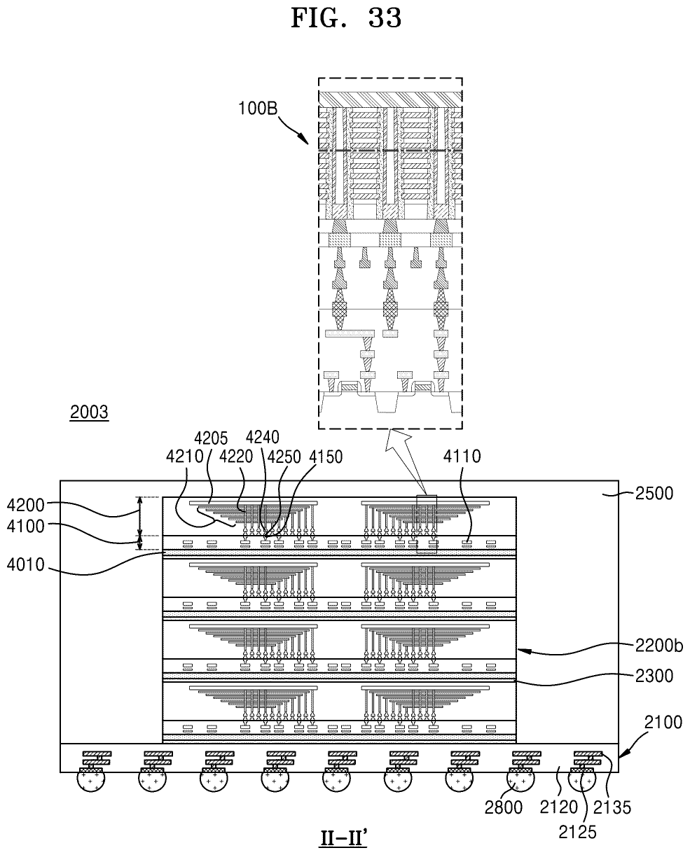

FIG. 33 is a cross-sectional view of semiconductor packages according to an example embodiment. FIG. 33 is a detailed view of a configuration taken along line II-II′ of FIG. 32.

Referring to FIG. 33, in a semiconductor package 2003, each of a plurality of semiconductor chips 2200b may include a semiconductor substrate 4010, a first structure 4100 on the semiconductor substrate 4010, and a second structure 4200 bonded to the first structure 4100 by using a wafer bonding technique on the first structure 4100.

The first structure 4100 may include a peripheral circuit region including peripheral wirings 4110 and first junction structures 4150. The second structure 4200 may include a common source line 4205, a gate stack structure 4210 between the common source line 4205 and the first structure 4100, memory channel structures 4220 passing through the gate stack structure 4210, and second junction structures 4250 respectively and electrically connected to the memory channel structures 4220 and word lines (refer to WL in FIG. 31) of the gate stack structure 4210. For example, the second junction structures 4250 may be respectively connected to the memory channel structures 4220 and the word lines (refer to WL in FIG. 31) through bit lines 4240 electrically connected to the memory channel structures 4220 and gate connection wirings electrically connected to the word lines WL. The first junction structures 4150 of the first structure 4100 may be in contact with and bonded to the second junction structures 4250 of the second structure 4200. Portions where the first junction structures 4150 are bonded to the second junction structures 4250 may include, for example, copper (Cu).

Each of the plurality of semiconductor chips 2200b may further include an I/O pad (refer to 2210 in FIG. 32), which is electrically connected to the peripheral wirings 4110 of the first structure 4100.

The plurality of semiconductor chips 2200 of FIG. 32 may be electrically connected to the plurality of semiconductor chips 2200b of FIG. 33 by a plurality of connection structures 2400 of bonding wire types. However, in some example embodiments, semiconductor chips (e.g., the plurality of semiconductor chips 2200 of FIG. 32 and the plurality of semiconductor chips 2200b of FIG. 33) in one semiconductor package may be electrically connected to each other by connection structures including TSVs.

Any functional blocks shown in the figures and described above may be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While the inventive concepts have been particularly shown and described with reference to some example embodiments thereof, it will be understood that various changes in form and details may be made therein without departing from the spirit and scope of the following claims.

What is claimed is:

1. A semiconductor device comprising:
a stack structure comprising a plurality of gate lines and a plurality of insulating patterns, the plurality of gate lines being apart from each other in a vertical direction, the plurality of insulating patterns being one-by-one between the plurality of gate lines, the stack structure including a vertical hole passing therethrough in the vertical direction;
a channel film extending in the vertical direction inside the vertical hole; and
a composite domain dielectric film between the channel film and the stack structure,
wherein the composite domain dielectric film comprises,
a main domain comprising a ferroelectric material, the main domain extending in the vertical direction inside the vertical hole, and
at least one sub-domain comprising at least one material selected from an anti-ferroelectric material and a paraelectric material, the at least one sub-domain being in contact with the main domain.

2. The semiconductor device of claim 1, wherein the composite domain dielectric film comprises:
a plurality of first dielectric regions facing the plurality of gate lines in a lateral direction, the plurality of first dielectric regions being apart from each other in the vertical direction; and
a plurality of second dielectric regions facing the plurality of insulating patterns in the lateral direction, the plurality of second dielectric regions being apart from each other in the vertical direction,
wherein the plurality of first dielectric regions have different stack structures and different widths in the lateral direction from the plurality of second dielectric regions.

3. The semiconductor device of claim 1, wherein the composite domain dielectric film comprises:
a plurality of first dielectric regions facing the plurality of gate lines in a lateral direction, the plurality of first dielectric regions being apart from each other in the vertical direction; and
a plurality of second dielectric regions facing the plurality of insulating patterns in the lateral direction, the plurality of second dielectric regions being apart from each other in the vertical direction,
wherein a width of each of the plurality of first dielectric regions is less than a width of each of the plurality of second dielectric regions in the lateral direction, and
the main domain faces each of the plurality of gate lines and the plurality of insulating patterns in the lateral direction, and
wherein the at least one sub-domain comprises,
a plurality of first sub-domains between the main domain and the plurality of insulating patterns, the plurality of first sub-domains being in contact with the main domain and being apart from each other in the vertical direction, and
a second sub-domain between the main domain and the channel film, the second sub-domain being in contact with the main domain and extending along the channel film in the vertical direction.

4. The semiconductor device of claim 1, wherein the main domain comprises:
a plurality of first main domain portions between the channel film and the plurality of gate lines; and
a plurality of second main domain portions between the channel film and the plurality of insulating patterns, the plurality of second main domain portions being integrally connected to the plurality of first main domain portions, respectively,
wherein a width in a lateral direction of each of the first main domain portions is less than a width in the lateral direction of each of the second main domain portions.

5. The semiconductor device of claim 1, further comprising:
a plurality of local composite dielectric films between the composite domain dielectric film and the plurality of gate lines,
wherein the plurality of local composite dielectric films are apart from each other in the vertical direction,
each of the plurality of local composite dielectric films comprises a first domain, a second domain, and a third domain, which are sequentially stacked from a corresponding one of the plurality of gate lines toward the composite domain dielectric film, and
each of the first domain and the third domain comprises at least one material selected from an anti-ferroelectric material and a paraelectric material, and the second domain comprises a ferroelectric material.

6. The semiconductor device of claim 1, wherein the main domain of the composite domain dielectric film faces each of the plurality of gate lines and the plurality of insulating patterns in a lateral direction,
wherein the at least one sub-domain comprises,
a plurality of first sub-domains between the main domain and the plurality of insulating patterns, the plurality of first sub-domains being in contact with the main domain and being apart from each other in the vertical direction, and
a second sub-domain between the main domain and the channel film, the second sub-domain being in contact with the main domain and extending along the channel film in the vertical direction, and
wherein each of the plurality of first sub-domains and the second sub-domain comprises an anti-ferroelectric material.

7. The semiconductor device of claim 1, wherein the main domain of the composite domain dielectric film faces the plurality of gate lines and the plurality of insulating patterns in a lateral direction,
wherein the at least one sub-domain comprises,
a plurality of first sub-domains between the main domain and the plurality of insulating patterns, the plurality of first sub-domains being in contact with the main domain and being apart from each other in the vertical direction, and
a second sub-domain between the main domain and the channel film, the second sub-domain being in contact with the main domain and extending along the channel film in the vertical direction, and
wherein each of the plurality of first sub-domains and the second sub-domain comprises a paraelectric material.

8. The semiconductor device of claim 1, wherein the at least one sub-domain of the composite domain dielectric film comprises:
a first sub-domain between the plurality of insulating patterns and the main domain, the first sub-domain being in contact with each of the plurality of insulating patterns and the main domain; and
a second sub-domain between the main domain and the channel film, the second sub-domain being in contact with the main domain and the channel film,
wherein a width in a lateral direction of the main domain is greater than a width in the lateral direction of each of the first sub-domain and the second sub-domain.

9. The semiconductor device of claim 1, wherein the channel film comprises polysilicon, an oxide semiconductor, a two-dimensional (2D) semiconductor material, or a combination thereof.

10. The semiconductor device of claim 1, wherein the channel film comprises:
a first channel film in contact with the composite domain dielectric film, the first channel film comprising a first channel material;
a second channel film apart from the composite domain dielectric film with the first channel film therebetween, the second channel film comprising a second channel material; and
the second channel material is different from the first channel material.

11. The semiconductor device of claim 1, wherein the composite domain dielectric film has an L-shaped sectional structure.

12. The semiconductor device of claim 1, wherein each of the plurality of insulating patterns comprises an air gap.

13. The semiconductor device of claim 1, wherein each of the channel film and the composite domain dielectric film comprises a curved surface facing the plurality of gate lines.

14. A semiconductor device comprising:
a conductive layer;
a stack structure comprising a plurality of gate lines and a plurality of insulating patterns, the plurality of gate lines overlapping each other in a vertical direction on the conductive layer, the plurality of gate lines being apart from each other in the vertical direction, the plurality of insulating patterns being one-by-one between the plurality of gate lines, the stack structure including a vertical hole passing therethrough in the vertical direction;
a conductive pad apart from the conductive layer with the stack structure therebetween in the vertical direction;
a channel film extending in the vertical direction inside the vertical hole, the channel film having a first channel end portion in contact with the conductive pad and a second channel end portion adjacent to the conductive layer;
an insulating plug surrounded by the channel film; and
a composite domain dielectric film between the channel film and the stack structure, the composite domain dielectric film having a first end portion in contact with the conductive pad and a second end portion in contact with the conductive layer,
wherein the composite domain dielectric film comprises,
a main domain comprising a ferroelectric material, the main domain extending in the vertical direction inside the vertical hole, and
at least one sub-domain comprising at least one material selected from an anti-ferroelectric material and a paraelectric material, the at least one sub-domain being in contact with the main domain.

15. The semiconductor device of claim 14, wherein a lateral width of the main domain of the composite domain dielectric film varies along the vertical direction.

16. The semiconductor device of claim 14, wherein the at least one sub-domain of the composite domain dielectric film comprises:
a first sub-domain between the plurality of insulating patterns and the main domain, the first sub-domain being in contact with each of the plurality of insulating patterns and the main domain; and
a second sub-domain between the main domain and the channel film, the second sub-domain being in contact with each of the main domain and the channel film,
wherein a width in a lateral direction of the main domain is greater than a width in the lateral direction of each of the first sub-domain and the second sub-domain.

17. The semiconductor device of claim 14, wherein the channel film comprises polysilicon, an oxide semiconductor, a two-dimensional (2D) semiconductor material, or a combination thereof.

18. The semiconductor device of claim 14, further comprising:
a plurality of local composite dielectric films between the composite domain dielectric film and the plurality of gate lines,
wherein the plurality of local composite dielectric films are apart from each other in the vertical direction,
each of the plurality of local composite dielectric films comprises a first domain, a second domain, and a third domain, which are sequentially stacked from a corresponding one of the plurality of gate lines toward the composite domain dielectric film, and
each of the first domain and the third domain comprises at least one material selected from an anti-ferroelectric material and a paraelectric material, and the second domain comprises a ferroelectric material.

19. An electronic system comprising:
a main substrate;
a semiconductor device on the main substrate; and
a controller electrically connected to the semiconductor device on the main substrate,
wherein the semiconductor device comprises,
a stack structure comprising a plurality of gate lines and a plurality of insulating patterns, the plurality of gate lines being apart from each other in a vertical direction, and the plurality of insulating patterns being one-by-one between the plurality of gate lines, the stack structure including a vertical hole passing therethrough in the vertical direction,
a channel film extending in the vertical direction inside the vertical hole, and
a composite domain dielectric film between the channel film and the stack structure, and
wherein the composite domain dielectric film comprises,
a main domain comprising a ferroelectric material, the main domain extending in the vertical direction inside the vertical hole, and
at least one sub-domain comprising at least one material selected from an anti-ferroelectric material and a paraelectric material, the at least one sub-domain being in contact with the main domain.

20. The electronic system of claim 19, wherein the main substrate further comprises wiring patterns configured to electrically connect the semiconductor device to the controller, and
a lateral width of the main domain of the composite domain dielectric film varies along the vertical direction in the semiconductor device,
wherein the at least one sub-domain of the composite domain dielectric film comprises,
a first sub-domain between the plurality of insulating patterns and the main domain, the first sub-domain being in contact with each of the plurality of insulating patterns and the main domain, and
a second sub-domain between the main domain and the channel film, the second sub-domain being in contact with each of the main domain and the channel film, and
wherein the lateral width of the main domain is greater than a lateral width of each of the first sub-domain and the second sub-domain.
